(19) United States
(12) Patent Application Publication
(10) Pub. No.: US 2010/0255323 A1
(43) Pub. Date: Oct. 7, 2010

(54) TRANSPARENT ELECTRODE, MANUFACTURING METHOD OF THE SAME AND ORGANIC ELECTROLUMINESCENCE ELEMENT

(75) Inventors: Kazuaki NAKAMURA, Tokyo (JP); Norio MIURA, Sagamihara-shi (JP); Akihiko TAKEDA, Sagamihara-shi (JP); Masaki GOTO, Tokyo (JP)

Correspondence Address: CANTOR COLBURN, LLP, 20 Church Street, 22nd Floor, Hartford, CT, 06103, US

(73) Assignee: KONICA MINOLTA HOLDINGS, INC.,, Tokyo (JP)

(21) Appl. No.: 12/749,664

(22) Filed: Mar. 30, 2010

(30) Foreign Application Priority Data
Apr. 2, 2009 (JP) 2009-089858

(51) Int. Cl. H01B 1/12; H01B 1/02; B05D 5/12; B32B 15/02; H01J 1/00

(52) U.S. Cl. 428/457; 252/500; 252/514; 427/66; 977/762; 977/932

(57) ABSTRACT

Disclosed is a transparent electrode including a transparent substrate having thereon a conductive fiber, a conductive polymer and a water soluble binder resin, wherein a content of the water soluble binder resin is in the range of 1 to 200 weight % based on a weight of the conductive polymer.

### CROSS REFERENCE TO RELATED APPLICATION

This application is based on Japanese Patent Application No. 2009-089858 filed on Apr. 2, 2009 with Japan Patent Office, the entire content of which is hereby incorporated by reference.

### TECHNICAL FIELD

The present invention relates to a transparent electrode, a method for manufacturing the same and an organic electroluminescence element (hereafter it is called as an organic EL element) using the same which are appropriately employable in various fields such as liquid crystal display elements, organic luminescence elements, inorganic electroluminescence elements, solar cells, electromagnetic wave shields, electronic papers or touch panels.

### BACKGROUND

In recent years, along with an increased demand for thinner TVs, there have been developed display technologies of various systems such as liquid crystals, plasma, organic electroluminescence, and field emission. In any of the displays which differ in the display system, transparent electrodes are incorporated therein as an essential constituting technology. Further, other than TVs, in touch panels, cellular phones, electronic paper, various solar cells, and various electroluminescence controlling elements, transparent electrodes have become an indispensable technical component.

Conventionally, as a transparent electrode, there has been mainly used an ITO transparent electrode having an indium-tin complex oxide (ITO) membrane produced by a vacuum deposition method or a sputtering process on transparent base materials, such as glass and a transparent plastic film. However, the indium used for ITO is a rare metal, and using no indium is desired by a substantial rise in prices. Moreover, it is required the manufacturing research and engineering of producing with a “roll-to-roll” method using a flexible base in connection with a display having a larger size, and improvement of productivity.

In recent years, there were disclosed technologies employing conductive fibers. It was proposed to form a transparent electrode in such a manner that some of a conductive fiber are fixed to a substrate by employing the transparent resin film and some of the conductive fibers are exposed or form projections on the surface of the transparent resin film (for example, refer to Patent document 1). However, the transparent electrode constituted as above only had electro-conductivity at the projected portion of the conducted fibers on the surface. This method had the problems to be solved that it cannot be applied to a flat electrode which is required to exhibit a uniform conductivity on the entire surface of the electrode.

Moreover, there was proposed a transparent flat electrode with a smooth electrode surface produced by overcoating polyurethane on the silver nanowires applied on a transparent substrate (for example, refer to Patent document 2). However, when the coating type organic EL element was laminated on this transparent electrode, it was revealed that it showed deteriorated surface lighting property and insufficient luminescence lifetime.

As for the average surface smoothness (Ra) of an ITO transparent conducting film surface used for an organic electroluminescence element, a smooth electrode of 10 nm or less is usually used. When the organic electroluminescence element was produced using the electrode in which a projection exists in a transparent electrode surface described in the above-mentioned Patent documents 1 and 2, there was a problem of short-circuiting with projections as the starting point, such as a short circuit between an anode and a cathode, and it had the problem that this phenomenon became outstanding further, under the ambience of the elevated temperature and high-humidity. Moreover, between projections, there exists a transparent resin, and it had problem that the function as a flat electrode was not fully obtained.

As forming transparent electrodes excellent in productivity, there were disclosed methods of applying a coating liquid prepared by dissolving or dispersing conductive polymer materials represented by n-conjugated polymers with coating or printing to form a transparent electrode (for example, refer to Patent Document 3). Moreover, there were proposed transparent electrodes formed by laminating electrical conductive polymers on silver nanowires (for example, refer to Patent Document 4). However, when compared to metal oxide transparent-electrodes such as ITO, which is prepared by a vacuum film preparing method, they exhibited lower electrical conductivity and degraded transparency. There remain problems to achieve both high transparency and high electrical conductivity at the same time.

Patent document 1: Japanese Patent Application Publication (hereafter it is called as JP-A) No. 2006-519712

Patent document 2: US 2007/0074316

Patent document 3: JP-A No. 6-273964

Patent document 4: US 2008/0259262

### SUMMARY

The present invention was made in view of the above-mentioned problems. An object of the present invention is to provide a transparent electrode which exhibits high conductivity and high transparency even if it is subjected to an environmental test under an elevated temperature and high humidity as well as shows good surface smoothness and is excellent in stability (total optical transmittance, surface resistivity and surface smoothness (Ra, Ry)). An object of the present invention is also to provide a production method of the aforesaid transparent electrode and an organic electroluminescence element excellent in the luminescence homogeneity using this transparent electrode.

The above problems related to the present invention can be solved by the following embodiments.

1. A transparent electrode comprising a transparent substrate having thereon a conductive fiber, a conductive polymer and a water soluble binder resin,

wherein a content of the water soluble binder resin is in the range of 1 to 200 weight % based on a weight of the conductive polymer.

2. The transparent electrode of the above-described item 1,

wherein the transparent substrate is provided with a transparent conductive layer containing the conductive fiber, the conductive polymer and the water soluble binder resin, and a content of the water soluble binder resin is in the range of 1 to 200 weight % based on a weight of the conductive polymer.

3. The transparent electrode of the above-described item 1,

wherein the transparent conductive layer comprises a first transparent conductive layer provided on the transparent substrate and a second transparent conductive layer provided on the first transparent conductive layer, the first transparent conductive layer containing the conductive fiber, and the second transparent conductive layer containing the conductive polymer and the water soluble binder resin, and a content of the water soluble binder resin is in the range of 1 to 200 weight % based on a weight of the conductive polymer.

4. The transparent electrode of any one of the above-described items 1 to 3,

wherein the content of the water soluble binder resin is in the range of 5 to 50 weight % based on the weight of the conductive polymer.

5. The transparent electrode of any one of the above-described items 1 to 4,

wherein the water soluble binder resin is a cross linking resin.

6. The transparent electrode of any one of the above-described items 1 to 5,

wherein the conductive fiber is a silver nanowire.

7. An electroluminescence element comprising the transparent electrode of any one of the above-described items 1 to 6.
8. A method for forming a transparent electrode comprising a step of:

applying a conductive fiber, a conductive polymer and a water soluble binder resin on a transparent substrate,

wherein a content of the water soluble binder resin is in the range of 1 to 200 weight % based on a weight of the conductive polymer.

9. The method for forming a transparent electrode of the above-described item 8,

wherein the applying step is done by coating with an aqueous dispersion containing water, the conductive fiber, the conductive polymer and the water soluble binder resin.

10. The method for forming a transparent electrode of the above-described item 8,

wherein the applying step comprises the flowing steps of:

coating a first solution containing the conductive fiber on the transparent substrate to form a first transparent conductive layer; and

coating a second solution containing the conductive polymer and the water soluble binder resin on the first transparent conductive layer to form a second transparent conductive layer.

11. The method for forming a transparent electrode of any one of the above-described items 8 to 10,

wherein a content of the water soluble binder resin is in the range of 5 to 50 weight % based on a weight of the conductive polymer.

12. The method for forming a transparent electrode of any one of the above-described items 8 to 11,

wherein the water soluble binder resin is a cross linking resin.

13. The method for forming a transparent electrode of any one of the above-described items 8 to 12,

wherein the conductive fiber is a silver nanowire.

According to the present invention, it is possible to provide a transparent electrode which exhibits high conductivity and high transparency even if it is subjected to an environmental test under an elevated temperature and high humidity as well as shows good surface smoothness and is excellent in stability (total optical transmittance, surface resistivity and surface smoothness (Ra, Ry)). And it is also possible to provide a production method of the aforesaid transparent electrode and an organic electroluminescence element excellent in the luminescence homogeneity using this transparent electrode.

### BRIEF DESCRIPTION OF THE DRAWINGS

FIGS. 1A to 1C are schematic diagrams showing the structure of the transparent electrode of the present invention.

### DESCRIPTION OF THE PREFERRED EMBODIMENTS

The embodiments to carry out the present invention are described in the followings, however, the present invention is not limited to these.

In the transparent electrode of the present invention which contains a transparent substrate having thereon a conductive fiber, a conductive polymer and a water soluble binder resin, the transparent electrode is characterized by containing the water soluble binder resin in an amount of 1 to 200 weight % with respect to the weight of a conductive polymer.

In the present invention, it is possible to achieve the following products by allowing to contain the water soluble binder resin in an amount of 1 to 200 weight % with respect to the weight of the conductive polymer. The achieved products by the present invention are: a transparent electrode which exhibits high conductivity and high transparency even if it is subjected to an environmental test under an elevated temperature and high humidity as well as shows good surface smoothness and is excellent in stability (total optical transmittance, surface resistivity and surface smoothness (Ra, Ry)); and an organic electroluminescence element excellent in the luminescence homogeneity using this transparent electrode.

The present invention is described in more detail.

### [Transparent Substrate]

In the present invention, “transparent” indicates a property which exhibits the total optical transmittance in the visible wavelength range of 60% or more when it is measured by the method based on “The test method of the total optical transmittance of a plastic transparent material” of JIS K 7361-1 (it corresponds to ISO 13468-1).

Transparent substrates employed in the present invention are not particularly limited as long as they exhibit high optical transparency. For example, appropriate substrates listed are glass substrates, resin substrates, and resin films in view of excellent hardness and easy formation of a conductive layer on their surfaces. However, in view of low weight and high flexibility, it is preferable to employ the transparent resin films.

Transparent resin films preferably employed in the present invention are not particularly limited, and their materials, shape, structure and thickness may be selected from those known in the art. Examples of the transparent resin films includes: polyester film (e.g., polyethylene terephthalate (PET) film, polyethylene naphthalate film, modified polyester film), polyolefin film (e.g., polyethylene (PE) film, polypropylene (PP) film, polystyrene film, cycloolefin resin film), vinyl resin film (e.g., polyvinyl chloride film, polyvinylidene chloride film), Polyether ether ketone (PEEK) film, polysulfone (PSF) film, polyethersulfone (PES) film, polycarbonate (PC) film, polyamide film, polyimide film, acrylic film, triacetyl cellulose (TAC) film. If the resin films have the transmittance of 80% or more in the visible wavelength (380-780 nm), they are preferably applicable to the transparent resin film of the present invention. It is especially preferable that they are a biaxially-drawn polyethylene terephthalate film, a biaxially-drawn polyethylene naphthalate film, a polyethersulfone film, and a polycarbonate film from a viewpoint of transparency, heat resistance, easy handling, strength and cost. Furthermore, it is more preferable that they are biaxially-drawn polyethylene terephthalate film and a biaxially-drawn polyethylene naphthalate film.

In order to secure the wettability and adhesion property of a coating solution, surface treatment can be performed and an adhesion assisting layer may be provided on the transparent substrate used for the present invention. A well-known technique can be used conventionally with respect to surface treatment or an adhesion assisting layer. Examples of surface treatment include: surface activating treatment such as: corona discharge treatment, flame treatment, ultraviolet treatment, high-frequency wave treatment, glow discharge process, active plasma treatment and laser treatment. Examples of materials for an adhesion assisting layer include: polyester, polyamide, polyurethane, vinyl copolymer, butadiene copolymer, acrylic copolymer, vinylidene copolymer and epoxy copolymer. When a transparent resin film is a biaxially-drawn polyethylene terephthalate film, it is more preferable to set the refractive index of the adhesion assisting layer which adjoins the transparent resin film to be 1.57-1.63 so as to reduce the interface reflection with the film substrate and the adhesion assisting layer and to result in improving transmittance. Adjusting a refractive index can be achieved by adjusting suitably the relation of the content of tin oxide sol or a cerium oxide sol which has a comparatively high refractive index with respect to the content of the binder resin, and then coating them on the film substrate. Although a single layer may be sufficient as the adhesion assisting, it may be the composition of two or more layers in order to raise adhesion property. Moreover, a barrier coat layer may be beforehand formed in the transparent substrate, and a hard coat layer may be beforehand formed in the opposite side on which a transparent conductive layer is transferred.

### [Transparent Electrode]

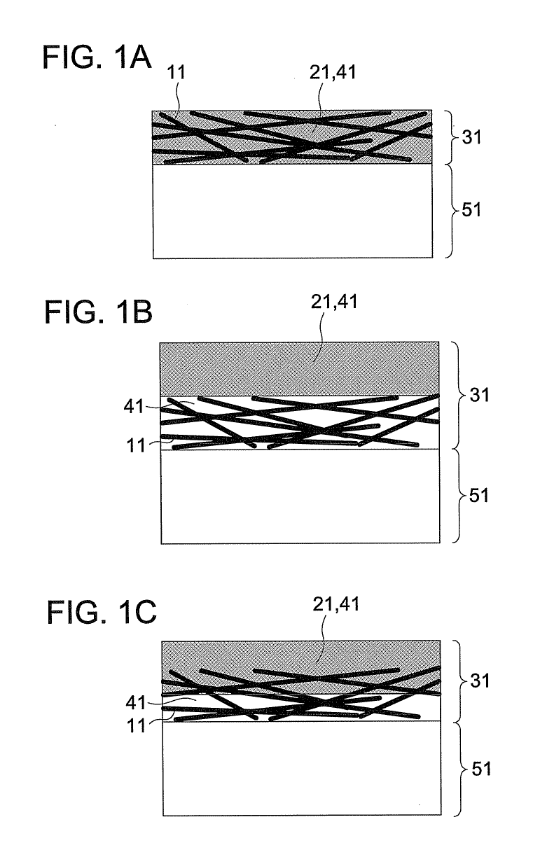

The schematic diagram showing the structure of the transparent electrode of the present invention is shown in FIGS. 1A to 1C. FIGS. 1A to 1C are structural diagrams of the typical transparent electrode of the present invention, it has transparent conductive layer 31 on transparent substrate 51, and this transparent conductive layer 31 is composed of conductive fiber 11 and conductive polymer 21 (conductive material). Water soluble resin 41 (transparent resin) is contained with the conductive polymer 21 in the transparent conductive layer 31. In the present invention, there is no restriction in particular to other composition.

In addition, surface treatment can be performed to a transparent substrate as mentioned above, or a various functionality layer can be prepared according to the object.

The total optical transmittance of the transparent electrode of the present invention is preferably at least 60%, it is more preferably at least 70%, but it is still most preferably at least 80%. It is possible to determine the total optical transmittance based on methods known in the art, employing a spectrophotometer. Further, the electrical resistance value of the transparent conductive layer of the transparent electrode is preferably at most 1,000Ω/□ in terms of surface resistivity, it is more preferably at most 100Ω/□. In order to apply to electric current driving type optoelectronic devices, it is preferably to be at most 50Ω/□, and it is specifically preferable to be at most 10Ω/□. When the transparent electrode has an electrical resistance value of 1,000Ω/□ or less, it is preferable since it can be used as a transparent electrode for a various kinds of electric current driving type optoelectronic devices. It is possible to determine the above surface resistivity, for example, based on JIS K7194: 1994 (Test method for resistivity of conductive plastics with a 4-pin probe measurement method) or ASTM D257. Further, it is also possible to conveniently determine the surface resistivity employing a commercially available surface resistivity meter.

The thickness of the transparent electrode of the present invention is not particularly limited, and it is possible to appropriately select the thickness depending on intended purposes. However, commonly the thickness is preferably at most 10 μm. The thickness is more preferably thinner since transparency and transparency are thereby improved in relation to the thickness.

### [Transparent Conductive Layer]

In one of the embodiments of the present invention, it is preferable that the conductive fiber is at least one selected from the group consisting of a metal nanowire and a carbon nanotube, and that the conductive material is at least one selected from the group consisting of a conductive polymer and a conductive metal oxide particle.

The transparent conductive layer of the present invention may contain a transparent binder material and an additive besides the conductive fiber and the conductive material. If it is a transparent resin which can form a coating solution, there will be no restriction in particular as a transparent binder material. Examples of the transparent resin include: polyester resin, polystyrene resin, acrylic resin, polyurethane resin, acrylic urethane resin, polycarbonate resin, cellulose resin and butyral resin. It can be used singly, or it can be used in combination of two or more.

The thickness of the transparent conductive layer of the present invention varies depending on the shape and the content of employed conductive fibers, but as a rough target, it is preferably from at least the average diameter of conductive fibers to at most 500 nm. It is preferable to decrease the thickness of the transparent conductive layer of the present invention with the pressing method which will be described later, since it is possible to closely form the network of the conductive fibers in the layer thickness direction.

### [Surface Smoothness]

In the present invention, Ry and Ra each respectively show the surface smoothness of the surface of a transparent conductive layer. They indicate respectively the following meanings: Ry=a maximum height (the vertical interval between the summit part and a bottom part in the surface); and Ra=an arithmetic mean roughness. The are specified based on JIS B601 (1994). The transparent electrode of the present invention preferably has the surface smoothness of the surface of the transparent conductive layer of Ry≦50 nm and at the same time it is preferable to have the surface smoothness of Ra≦5 nm. In the present invention, a commercially available atomic force microscope (AFM) can be used for measurement of Ry and Ra. For example, they can be measured by the following ways.

As an AFM, SPI3800N probe station and an SPA400 multifunctional-capability type module made by Seiko Instruments Co., Ltd., are used. The sample cut off in a square having a side of about 1 cm is set on a level sample stand on a piezo scanner, then, a cantilever is allowed to approach to a surface of the sample. When the cantilever reaches the region where an atomic force can function, the cantilever is scanned in the XY direction, and irregularity of the surface of the sample is caught by displacement of the piezo element in the Z direction. A piezo scanner which can scan the XY direction of 20 μm and the Z direction of 2 μm is used for the measurement. A cantilever used is silicon cantilever SI-DF20 made by Seiko Instruments Co., Ltd., and measurement is done in a DFM mode (Dynamic Force Mode) using the resonant frequency of 120-150 kHz, the spring constant of 12-20 N/m. The portion of 80×80 μm is measured with the scanning frequency of 1 Hz.

In the present invention, the value Ry is more preferably to be 40 nm or less, and it is still more preferably to be 30 nm or less. Similarly, the value Ra is more preferably to be 3 nm or less, and i it is still more preferably to be 1 nm or less.

### [Conductive Fiber]

The conductive fiber concerning the present invention has conductivity, and has a form with a length long enough compared with a diameter (thickness). It is thought that the conductive fiber of the present invention forms a three-dimensional conductive network when a conductive fiber contacts each other in a transparent conductive layer, and it functions as an auxiliary electrode. Therefore, it is preferable to use a conductive fiber having a longer length since it is advantageous to form a conductive network. On the other hand, when a conductive fiber becomes long, a conductive fiber will become entangled resulting in forming an aggregate, which may deteriorate an optical property. It is preferable to use the conductive fiber of the optimal average aspect ratio (aspect ratio=length/diameter) according to the conductive fiber to be used, since the rigidity of a conductive fiber, a diameter or other properties may affect the formation of the conductive network and aggregate. As for an average aspect ratio, as a near rough indication, it is preferable to be 10-10,000.

As a form of a conductive fiber, there are known several shapes such as a hollow tube, a wire and a fiber. For example, there are an organic fiber coated with metal, an inorganic fiber, a conductive metal oxide fiber, a metal nanowire, a carbon fiber and a carbon nanotube. In the present invention, it is preferable that the thickness of a conductive fiber is 300 nm or less from a viewpoint of transparency. In addition, in order to also satisfy conductivity of a conductive fiber, it is preferable that the used conductive fiber is at least one selected from the group consisting of a metal nanowire and a carbon nanotube. Furthermore, a silver nanowire can be most preferably used from a viewpoint of cost (a material cost, a cost of production) and properties (electro-conductivity, transparency and flexibility).

In the present invention, it is possible to determine the above average diameter and average aspect ratio of the conductive fibers as follows. A sufficient number of electron microscopic images are taken. Subsequently, each of the conductive fiber images is measured and the arithmetic average is obtained. The length of conductive fibers should fundamentally be determined in a stretched state to become a straight line. In reality, in most cases, they are curved. Consequently, by employing electron microscopic images, the projected diameter and projected area of each of the nanowires were calculated employing an image analysis apparatus and calculation is carried out while assuming a cylindrical column (length=projected area/projected diameter). A relative standard deviation of length or diameter is represented with a value obtained from the standard deviation value of the measured values divided by the average value of the measured values, which is multiplied by 100. The number of nanowires to be measured is preferably at least 100, but is more preferably at least 300.

Relative standard deviation(%)=(Standard deviation value of the measured values/average value of the measured values)×100

### [Metal Nanowires]

Generally, metal nanowires indicate a linear structure composed of a metallic element as a main structural element. In particular, the metal nanowires in the present invention indicate a linear structure having a diameter of from an atomic scale to a nanometer (nm) size.

In order to form a long conductive path by one metal nanowire, a metal nanowire applied to the conductive fibers concerning the present invention is preferably have an average length of 3 μm or more, more preferably it is 3-500 μm, and still more it is 3-300 μm. In addition, the relative standard deviation of the length of the conductive fibers is preferably 40% or less. Moreover, from a viewpoint of transparency, a smaller average diameter is preferable, on the other hand, a larger average diameter is preferable from a conductive viewpoint. In the present invention, 10-300 nm is preferable as an average diameter of metal nanowires, and it is more preferable to be 30-200 nm. Further, the relative standard deviation of the diameter is preferably to be 20% or less.

There is no restriction in particular to the metal composition of the metal nanowire of the present invention, and it can be composed of one sort or two or more metals of noble metal elements or base metal elements. It is preferable that it contains at least one sort of metal selected from the group consisting of noble metals (for example, gold, platinum, silver, palladium, rhodium, iridium, ruthenium and osmium), iron, cobalt, copper and tin. It is more preferable that silver is included in it at least from a conductive viewpoint. Moreover, for the purpose of achieving compatibility of conductivity and stability (sulfuration resistance and oxidation resistance of metal nanowire and migration resistance of metal nanowire), it is also preferable that it contains silver and at least one sort of metal belonging to the noble metal except silver. When the metal nanowire of the present invention contains two or more kinds of metallic elements, metal composition may be different between the surface and the inside of metal nanowire, and the whole metal nanowire may have the same metal composition.

In the present invention, there is no restriction in particular to the production means of metal nanowires. It is possible to prepare metal nanowires via various methods such as a liquid phase method or a gas phase method. For example, the manufacturing method of Ag nanowires may be referred to Adv. Mater. 2002, 14, 833-837 and Chem. Mater. 2002, 14, 4736-4745; a manufacturing method of Au nanowires may be referred to JP-A No. 2006-233252; the manufacturing method of Cu nanowires may be referred to JP-A No. 2002-266007; while the manufacturing method of Co nanowires may be referred to JP-A No. 2004-149871. Specifically, the manufacturing methods of Ag nanowires, described in Adv. Mater. 2002, 14, 833-837 and Chem. Mater. 2002, 14, 4736-4745, may be preferably employed as a manufacturing method of the metal nanowires according to the present invention, since via those methods, it is possible to simply prepare a large amount of Ag nanowires in an aqueous system and the electrical conductivity of silver is highest of all metals.

### [Carbon Nanotube]

Carbon nanotubes are a carbon fiber material having a cylindrical shape formed with graphite-like carbon atom surfaces (graphene seats) of a thickness of several atomic layers. Carbon nanotubes are divided roughly into a single layer nanotube (SWNT) and a multilayer nanotube (MWNT) from the composition numbers of the peripheral walls of the tube. Moreover, it is divided into a chiral (spiral) type, a zigzag type, and an armchair type from the difference in the structure of a graphene seat, thus there are known various types of carbon nanotube.

As a carbon nanotube applied to the conductive fiber concerning the present invention, any types of carbon nanotube can be used, and more than one type of these various carbon nanotubes may be used by mixing. In the present invention, it is preferable to employ single layer nanotubes which excel in electro-conductivity, and further, it is preferable to employ metallic armchair type single layer carbon nanotubes.

In order to form a long conductive path by one carbon nanotube, the shape of the carbon nanotube of the present invention is preferably have a large aspect ratio (aspect ratio=length/diameter), namely, it is preferable that the carbon nanotube is thin and long single layer carbon nanotube. For example, carbon nanotubes having an aspect ration of 102, more preferably having an aspect ratio 103 or more can be cited for preferable carbon nanotubes. An average length of carbon nanotubes is preferably 3 μm or more, and more preferably it is 3-500 μm, and still more preferably it is 3-300 μm. In addition, the relative standard deviation of the length is preferably to be 40% or less. Moreover, an average diameter is preferably to be smaller than 100 nm, more preferably it is 1-50 nm, and still more preferably, it is 1-30 nm. In addition, the relative standard deviation of the diameter is preferably to be 20% or less.

The production method of the carbon nanotubes used in the present invention is not limited in particular. It can be used well-known means, such as catalytic hydrogen reduction of carbon dioxide, arc discharge process, laser evaporating method, CVD method, vapor growth method, and HiPco method in which carbon monoxide is allowed to react with an iron catalyst at an elevated-temperature with a high pressure and make it grow up in a gas phase. Moreover, in order to remove the residues of the reaction, such as byproducts and catalyst metals, it is preferable to highly purify the carbon nanotubes by various refining processes, such as with washing method, centrifuge method, filtration, oxidation method, and chromatography so as to fully exhibiting the various functions of the carbon nanotubes.

### [Conductive Material]

In the present invention, a conductive material is a material which exhibits transparency and uniform conductivity when a film is formed with this material. As such a conductive material, there are known, for example, a conductive polymer, conductive metal oxide particles, metal particles, organic particles coated with metal and inorganic particles. In the present invention, from the viewpoint of transparency and conductivity, it is preferable that the conductive material is at least one selected from the group consisting of a conductive polymer or a conductive metal oxide nanoparticle.

### [Conductive Polymer]

Examples of a conductive polymer employed for the conductive material in the present invention include compounds selected from the group consisting of each of the derivatives of: polypyrrole, polyaniline, polythiophene, polythienylene vinylene, polyazulene, polyisothianaphthene, polycarbazole, polyacetylene, polyphenylene, polyphenylene vinylene, polyacene, polyphenyl acetylene and polynaphthalene.

The conductive material of the present invention may incorporate only one type of a conductive polymer alone or at least two types of conductive polymers in combination. In view of electrical conductivity and transparency, it is more preferable to incorporate at least one compound selected from the group consisting of polyaniline having the repeated unit represented by the following Formula (I) and/or the following Formula (II) and derivatives thereof, polypyrrole derivatives having the repeated unit represented by the following Formula (III), and polythiophene derivatives having the repeated unit represented by the following Formula (Iv).

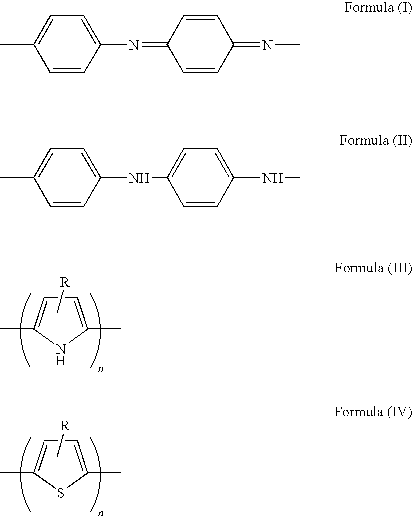

In above Formula (III) and Formula (IV), R is primarily a linear organic substituent, which is preferably an alkyl group, an alkoxy group, or an allyl group, or a combination thereof. Further, these may be combined with a sulfonate group, an ester group, or an amido group or a combination thereof. These may be usable when properties as a soluble conductive polymer are not lost. Still further, “n” is an integer.

Conductive polymers employed in the present invention may be subjected to doping treatment to further enhance electro-conductivity. Examples of a dopant used for conductive polymers include at least one selected from the group consisting of sulfonic acids (hereinafter referred to as “long chain sulfonic acids”) having a hydrocarbon group with 6-30 carbon atoms or polymers thereof (for example, polystyrenesulfonic acid) or derivatives thereof, halogens, Lewis acids, protonic acids, transition metal halides, transition metal compounds, alkaline metals, alkaline earth metals, MClO₄ (M=Li⁺ or Na⁺), R₄N⁺ (R═CH₃, C₄H₉, or C₆H₅), or R₄P⁺ (R═CH₃, C₄H₉, or C₆H₅). Of these, the above long chain sulfonic acid is preferred.

Further, the dopants used for conductive polymers may be incorporated into fullerenes such as hydrogenated fullerene, hydroxylated fullerene, or sulfonated fullerene. In the transparent conductive layer of the present invention, the content of the above dopants is preferably at least 0.001 part by weight with respect to 100 parts by weight of the conductive polymers, but it is more preferably at least 0.5 part by weight.

The conductive materials of the present may incorporate at least one dopant selected from the group consisting of a long chain sulfonic acida, polymers of the long chain sulfonic acid (for example, polystyrenesulfonic acid), halogens, Lewis acids, protonic acids, transition metal halides, transition metal compounds, alkaline metals, alkaline earth metals, MClO₄, R₄N⁺, and R₄P⁺, together with fullerenes.

As the conductive polymers according to the present invention, employed may be conductive polymers modified via metal, disclosed in each of JP-A Nos. 2001-511581, 2004-99640 and 2007-165199.

Conductive materials which include conductive polymers according to the present invention may incorporate water soluble organic compounds. There are known compounds which exhibit effects to enhance electro-conductivity via addition to a conductive polymer, and they are occasionally called a 2^{nd} dopant (or a sensitizer). The 2^{nd} dopants which are usable in the present invention are not particularly limited, and it is possible to appropriately select them from those known in the art. Preferred examples include oxygen-containing compounds such as dimethyl sulfoxide (DMSO) and diethylene glycol.

The content of the above-described 2^{nd} dopants in the conductive materials incorporating a conductive polymer of the present invention is preferably at least 0.001 part by weight with respect to 100 parts by weight of the conductive polymer, it is more preferably 0.01-50 parts by weight, but it is most preferably 0.01-10 parts by weight.

In order to assure film forming properties and film strength, the conductive materials incorporating a conductive polymer of to the present invention may incorporate transparent resin components and additives, other than the above-described conductive polymers. With regard to transparent resin components, the resin components are not particularly limited as long as they are compatible with or mix dispersible with the conductive polymers. They may be thermally curable resins or thermoplastic resins. Examples of the transparent resin include: polyester resin (e.g., polyethylene terephthalate, polybutylene terephthalate and polyethylene naphthalate), polyimide resin (e.g., polyimide resin and polyamideimide resin), polyamide resin (e.g., polyamide 6, polyamide 6,6, polyamide 12 and polyamide 11), fluororesin (e.g., polyvinylidene fluoride, polyvinyl fluoride, polytetrafluoroethylene, ethylene-tetrafluoroethylene copolymer, polychlorotrifluoroethylene), vinyl resin (e.g., polyvinyl alcohol, polyvinyl ether, polyvinyl butyral, polyvinyl acetate, polyvinyl chloride), epoxy resin, xylene resin, aramid resin, polyurethane resin, polyurea resin, melamine resin, phenol resin, polyether, acrylic resin and copolymers thereof.

A polyanion which may me used in the present invention can be a compound selected from the group consisting of a polymer carboxylic acid, a polymer sulfonic acid and their salts. It is preferable to use a polymer sulfonic acid and a salt thereof. A polyanion may be contained singly and may be contained in combination of two or more kinds. Moreover, a polyanion may form a copolymer of a structural unit which has carboxylic acid and sulfonic acid with a monomer which does not have acid residue, for example, a acrylate, methacrylate or styrene.

Examples of a polymer carboxylic acid, a polymer sulfonic acid and their salts include: polyacrylic acid, polymethacrylic acid, polymaleic acid, polymer sulfonic acid, polystyrene sulfonate, polyvinyl sulfonic acid and the salts of these compounds. Polystyrene sulfonate and its salt are preferably used.

### [Water Soluble Binder Resin]

In the transparent electrode of the present invention which contains a transparent substrate having thereon a conductive fiber, a conductive polymer and a water soluble binder resin, the transparent electrode is characterized by containing the water soluble binder resin in an amount of 1 to 200 weight with respect to the weight of the conductive polymer.

The water soluble binder resin of the present invention is a resin which can be dissolved in an amount of 0.001 g or more in 100 g of water at 25° C.

The above-mentioned dissolution can be measured with a haze meter and a turbidimeter.

It is preferable that the water soluble binder resin of the present invention is transparent.

As a water soluble binder of the present invention, there is no restriction in particular as long as it is a medium to form a film such as a natural polymer, a synthetic resin, a synthetic polymer, a synthetic copolymer, and other materials. Examples the water soluble binder include: gelatin, casein, starch, gum arabic, poly(vinyl alcohol), poly(vinyl pyrrolidone), cellulose derivatives (e.g., carboxymethyl ether cellulose, hydroxyethyl cellulose, methylhydroxyethyl ether cellulose), chitosan, dextran, guar gum, poly(acrylamide), poly(acrylamide acrylic acid), poly(acrylic acid), poly(methacrylic acid), poly(allylamine), poly(butadiene-maleic anhydride), poly(n-butyl acrylate-2-methacryloyl trimethyl ammonium bromide), poly(3-chloro-2-hydroxypropyl-2-methacryloxy trimethyl ammonium bromide), poly(2-dimethylaminoethyl methacrylate), poly(ethylene glycol), poly(ethylene glycol)-bisphenol A-diglycidyl ether adduct, poly(ethylene glycol) bis-2-aminoethyl, poly(ethylene glycol) dimethyl ether, poly(ethylene glycol) monocarboxymethyl ether monomethyl ether, poly(ethylene glycol) monomethyl ether, poly(ethylene oxide), poly(ethylene oxide-b-propylene oxide), polyethyleneimine, poly(2-ethyl-2-oxazoline), poly(1-glycerol methacrylate), poly(2-hydroxyethyl acrylate), poly(2-ethyl methacrylate), poly(2-hydroxyethyl methacrylate methacrylic acid), poly(maleic acid), poly(methacrylamide), poly(2-metahcryloxyethyl trimethyl ammonium bromide), poly(N-iso-propylacrylamide), poly(styrene sulfonic acid), poly(N-vinylacetamide), poly(N-methyl-N-vinylacetamide), poly(vinylamine), poly(2-vinyl-1-methylpyridinium bromide), poly(phosphoric acid), poly(2-vinylpyridine), poly(4-vinylpyridine), poly(2-vinylpyridine N-oxide) and poly(vinylsulfonic acid). In the above-mentioned binders, the polymer which has a carboxyl group, a sulfo group, or a phosphoric acid group, may have salt of such as lithium, sodium, and potassium, and the polymer which has a nitrogen atom may have the structure of a hydrochloride. Moreover, a melamine resin, a urea resin, and a glyoxal resin, which are thermosetting resin can be cited. The above-mentioned binder can be used singly or two or more sorts may be used in combination.

Among water soluble binders of the present invention, preferable compounds are: gelatin, poly(vinyl alcohol), poly(vinyl pyrrolidone), cellulose derivatives, poly(acrylic acid), poly(ethylene glycol), poly(2-hydroxyethyl acrylate), poly(2-ethyl methacrylate), poly(vinylsulfonic acid), a melamine resin, a urea resin and a glyoxal resin. More preferable compounds are: poly(vinyl alcohol), cellulose derivatives, poly(2-ethyl methacrylate), a melamine resin, a urea resin and a glyoxal resin.

It may be used commercially available compounds such as: PVA 203, PVA 224, EXEVAL RS-4104 (made by Kuraray Co., Ltd.); METOLOSE 90SH-100, METOLOSE 60SH-50, METOLOSE 60SH-06 (made by Shin-Etsu Chemical Co., Ltd.); and BECKAMINE M-3, BECKAMINE J-101, BECKAMINE N-80, BECKAMINE DC-W (made by DIC Co., Ltd.).

As an amount of the water soluble binder used in the present invention, it is preferable to use 1-200 weight % based on the weight of the conductive polymer, and it is more preferably 5 to 100 weight %, and still more preferably it is 5 to 50 weight %.

### [Manufacturing Methods]

In the production method'of the transparent electrode of the present invention, there is no restriction in particular to the methods of forming the auxiliary electrode composed of conductive fibers, and the transparent conductive layer containing a conductive (or it may be called as “electro-conductive”) material on a transparent substrate. However, in view of productivity and production cost, electrode qualities such as smoothness and uniformity, as well as reduction of environmental load, in order to form the transparent conductive layer, it is preferable to employ liquid phase film forming methods such as coating methods or printing methods. As the coating method employed may be a roller coating method, a bar coating method, a dip coating method, a spin coating method, a casting method, a die coating method, a blade coating method, a bar coating method, a gravure coating method, a curtain coating method, a spray coating method, and a doctor coating method, while as the printing method employed may be a letterpress (typographic) printing method, a porous (screen) printing method, a lithographic (offset) printing method, an intaglio (gravure) printing, a spray printing method, and an ink-jet printing method. As preliminary treatment to enhance close contact and coatability, if desired, the surface of a mold-releasing substrate may be subjected to physical surface treatment such as corona discharge treatment or plasma discharge treatment.

In the production method of the transparent electrode of the present invention, after forming a transparent conductive layer containing a conductive fiber and a conductive material on the mold-releasing surface of a smooth mold-releasing substrate, it is preferable to transfer this transparent conductive layer on a transparent substrate so as to form a transparent electrode. By using this way, the surface of the transparent conductive layer of the transparent electrode can be made to be highly smooth in a simple and stable manner.

As a mold-releasing substrate employed in the manufacturing method of the transparent electrode of the present invention, appropriately listed are resin substrates and resin films. The above resins are not particularly limited, and it is possible to appropriately select any of those known in the art. For example, appropriately employed are substrates and films, each of which is structured of a single layer or a plurality of layers composed of synthetic resins such as a polyethylene terephthalate resin, a vinyl chloride resin, an acrylic resin, a polycarbonate resin, a polyimide resin, a polyethylene resin, or a polypropylene resin. Further employed may be a glass substrate and a metal substrate. Further, if desired, the surface (the mold-releasing surface) of mold-releasing substrates may be subjected to surface treatment via application of a releasing agent such as a silicone resin, a fluororesin, or a wax.

Since a mold-releasing substrate surface affects the surface smoothness of the surface after transferring a transparent conductive layer, it is preferable that the mold-releasing substrate has high smoothness (Ry and Ra), it is preferable to have Ry≦50 nm, it is more preferable to have Ry≦40 nm, and it is still more preferable to have Ry≦30 nm. Moreover, it is preferable to have Ra≦5 nm, it is more preferable to have Ra≦3 nm, and it is still more preferable to have Ra≦1 nm.

The following processes can be cited, for example as a concrete way of forming the transparent conductive layer excellent in the surface smoothness containing a conductive fiber and a conductive material on a transparent substrate.

On a mold-releasing surface of a mold-releasing substrate, a conductive network structure made of conductive fibers is formed by applying (or printing) a dispersion liquid containing a conductive fiber followed by drying. Subsequently, a dispersion liquid of a conductive material is applied (or printed) on the network structure of the conductive fibers, thereby the space between the network structures of the conductive fibers on the substrate surface is filled with the conductive material, and a transparent conductive layer containing the conductive fiber and the conductive material is formed. Subsequently, on this transparent conductive layer or on another transparent substrate, an adhesive layer is provided and both the transparent conductive layer and the adhesive layer are adhered. After curing the adhesive layer, the transparent conductive layer is transferred to the transparent substrate by peeling off the mold-releasing substrate.

According to this process, since the network structure of a conductive fiber is arranged in three dimensions in a conductive material layer, the contact area of the conductive fiber and the conductive material can be increased, the auxiliary electrode function of the conductive fiber can fully be utilized, and the transparent conductive layer excellent in conductivity can be formed.

In the above-mentioned process, it is effective as a way of increasing the conductivity of the network structure of the conductive fiber to perform a calendar process and heat treatment so as to improve the adhesion between the conductive fibers after applying and drying the conductive fiber, or to perform plasma treatment so as to reduce the contact resistance between the conductive fibers. Moreover, in the above-mentioned process, hydrophilization treatment such as corona discharge (plasma) treatment may be beforehand carried out onto the mold-releasing surface of the mold-releasing substrate.

In the above-mentioned process, the adhesive layer may be prepared on the mold-releasing substrate side, and it may be prepared in the transparent substrate side. As an adhesive agent used for the adhesive layer, it will not be limited in particular, as long as it is transparent in the visible region, and as long as it has transfer ability. It may be a thermosetting resin or thermo plastic resin.

Although a thermosetting resin, a ultraviolet curing resin, an electron beam curing resin are cited as examples of a curable resin, among these curable resins, since the appliance for resin curing is simple, and it excels in working property, it is preferable to use a ultraviolet curing resin. A ultraviolet curing resin is a resin which is hardened through a cross linkage reaction by UV irradiation, and the ingredient containing the monomer which has an ethylenic unsaturated double bond is used preferably. For example, an acrylic urethane resin, a polyester-acrylates resin, an epoxy acrylate resin and a polyacrylate resin are cited. In the present invention, it is preferable to use a ultraviolet curing resin of an acrylic system and an acrylic urethane system as a main ingredient of a binder.

An acrylic urethane resin can be easily obtained by allowing to react an acryrate monomer having a hydroxyl group with the product generally acquired by the reaction of a polyester polyol with an isocyanate monomer or a prepolymer. Examples of the acryrate monomer having a hydroxyl group include: 2-hydroxyethyl acrylate, 2-hydroxyethyl methacrylate (hereafter, in the term “acrylate” it includes both “acrylate” and “methacrylate”) and 2-hydroxypropyl acrylate. For example, the compound described in JP-A No. 59-151110 can be used. More specifically, the mixture of 100 part of UNIDIC 17-806 (made by DIC Co., Ltd.) and 1 part of CORONATE L (made by Nippon Polyurethane Industry Co., Ltd.) is used preferably.

As an example of ultraviolet curing polyester-acrylates resin, it can be cited a compound which is formed easily by the reaction of a polyester polyol with a monomer such as 2-hydroxyethyl acrylate or 2-hydroxy acrylate. The compound described in JP-A No. 59-151112 can be used.

As an example of a ultraviolet curing epoxy acrylate resin, it can be cited a compound which can be produced by the following process: epoxy acrylate is made into an oligomer, then a reactive diluent and a photoinitiator are added and allowed to react with the oligomer to obtain the target compound. The compound described in JP-A No. 1-105738 can be used.

Examples of a ultraviolet curing polyol polyacrylate resin include: trimethylolpropane triacrylate, ditrimethylolpropane tetraacrylate, pentaerythritol triacrylate, pentaerythritol tetraacrylate, dipentaerythritol hexaacrylate and alkyl modified dipentaerythritol pentaacrylate.

As a resin monomer, conventional monomers having an unsaturated double bond can be cited, and examples of such monomer include: methyl acrylate, ethyl acrylate, butyl acrylate, benzyl acrylate, a cyclohexyl acrylate, vinyl acetate and styrene. Examples of monomers having two or more unsaturated double bonds are: ethylene glycol diacrylate, propylene glycol diacrylate, divinylbenzne, 1,4-cyclohexane diacrylate, 1,4-cyclohexyldimethyladiacrylate, trimethylolpropane triacrylate and pentaerythritol tetraacrylate.

Among these, a preferable compound to be used as a main ingredient of a binder is an acrylic actinic-ray curable resin. Examples of this include: 1,4-cyclohexane diacrylate, pentaerythritol tetra(meth)acrylate, pentaerythritol tri(meth)acrylate, trimethylolpropane (meth)acrylate, trimethylolethane (meth)acrylate, dipentaerythritol tetra(meth)acrylate, dipentaerythritol penta(meth)acrylate, dipentaerythritol hexa(meth)acrylate, 1,2,3-cyclohexanetetra methacrylate, polyurethane polyacrylate and polyester polyacrylate.

As a photoinitiator for these ultraviolet curing resins, specifically cited compounds are: benzoin, acetophenone, benzophenone, hydroxybenzophenone, Michler's ketone, α-amyloxim ester, thioxanthone and their derivatives. The photoinitiator may be used with a photosensitizer. The above-mentioned photoinitiator can also be used as a photosensitizer. Moreover, sensitizers such as n-butylamine, triethylamine and tri-n-butylphosphine can be used when the photoinitiator of an epoxy acrylate is employed. The amount of the photoinitiator or the amount of the photosensitizer used for a ultraviolet curing resin composition is 0.1-15 weight parts with respect to 100 weight parts of the composition, and it is preferably 1-10 weight parts.

After pasting together the mold-releasing substrate on which the transparent conductive layer was formed with the transparent substrate material, the adhesive agent is cured by irradiating with a UV light, then a transparent conductive layer can be transferred to the transparent substrate side by peeling off the mold-releasing substrate from the cured adhesive agent. Here, the adhesion way is not restricted in particular. Although a sheet press machine or a roll press machine can be used for adhesion, it is preferable to use a roll press machine. A roll press machine is preferably used since it can give pressure uniformly and its manufacturing efficiency is better than a sheet press machine.

### [Patterning Method]

The transparent conductive layer concerning the present invention can be patterned. There is no restriction in particular to the method and process of patterning, and a well-known approach can be applied suitably. For example, after forming the patterned transparent conductive layer on the mold-releasing surface, then by transferring the transparent conductive layer onto a transparent substrate, the patterned transparent electrode can be obtained. Specifically; the following methods can be' preferably used.

(i) The method in which a transparent conductive layer of the present invention is directly built in a pattern by using a printing method on a mold-releasing substrate.
(ii) The method in which a transparent conductive layer of the present invention is uniformly built on a mold-releasing substrate followed by carrying out pattering by a conventional photolithographic process.
(iii) The method in which a transparent conductive layer of the present invention is uniformly built on a mold-releasing substrate using a conductive material containing a UV curable resin followed by carrying out pattering in the same manner as a photolithographic process.
(iv) The method in which a transparent conductive layer of the present invention is uniformly built a negative pattern using a photoresist which has been provided on a mold-releasing substrate, then patterning using a lift off method is carried out.

By using any one of the above-mentioned methods, the patterned transparent electrode of the present invention can be formed by transferring the patterned transparent conductive layer produced on the mold-releasing substrate onto a transparent substrate.

### [Appropriate Application]

The transparent electrode of the present invention has high conductivity and transparency, and it can be used conveniently in the field of various optoelectronic devices such as liquid crystal display elements, organic electroluminescence elements, inorganic electroluminescence elements, electronic papers, organic solar cells, and inorganic solar cells; electromagnetic wave shields and touch panels. Among them, it can be suitably used for an organic electroluminescence element which is severely required the surface smoothness of the surface of a transparent electrode or for a transparent electrode of an organic thin film solar battery element.

### EXAMPLES

The present invention is described below with reference to examples, but the present invention is not limited to these. In examples, “part” or “t” may be used. Unless particularly mentioned, each respectively represents “weight part” or “weight %”.

### [Preparation of Silver Nanowire]

A silver nanowire was produced by the following method with reference to the method disclosed in Non-patent document 2.

### (Nucleation Process)

One hundred ml of an ethylene glycol (EG) solution of silver nitrate (silver nitrate concentration: 1.5×10⁻⁴ mol/L) was added in 10 seconds with a fixed flow rate to a reaction vessel containing 1,000 ml of EG agitated and kept at 170° C. Then, ripening was carried out for 10 minutes at 170° C., and silver nucleus particles were formed. The reaction liquid after termination of the ripening exhibited a yellow color originated from surface plasmon absorption of the silver nanoparticles. It was confirmed that silver ions were reduced to form silver nanoparticles.

### (Grain Growth Process)

With keeping at 170° C. and agitating the reaction liquid containing the nucleus particles which ended the above-mentioned ripening, there were added 1,000 ml of EG solution of silver nitrate (silver nitrate concentration: 1.0×10⁻¹ mol/L) and 1,000 ml of EG solution of PVP K30 (molecular weight 50,000; made by ISP Co., Ltd.) (VP converted concentration: 5.0×10⁻¹ mol/L) in 100 minutes with a fixed flow rate using a double-jet precipitation method. When the reaction liquid was extracted every 20 minutes during the grain growth manufacturing process and having been checked with the electron microscope, the silver nanoparticles formed at the nucleation process had mainly grown to a long axis direction of a nanowire with time progress, and formation of a new nucleus particle was not detected during a grain growth process.

### (Washing Process)

After termination of the grain growth process, the reaction liquid was cooled to room temperature, it was filtered using a filter and the obtained silver nanowires were dispersed again into ethanol. Filtration of the silver nanowires with a filter and the re-dispersion into ethanol were repeated 5 times, the water dispersion of silver nanowire was finally prepared, and silver nanowires were produced.

A small amount of sample was extracted from the obtained dispersion liquid and it was checked with the electron microscope, it was confirmed that the silver nanowires with an average diameter of 85 nm and an average length of 7.4 μm were formed.

### Example 1

### Preparation of Transparent Electrode TC-101

### Present Invention

On a polyethylene terephthalate film support with a thickness of 100 μm which had been performed adhesion assisting treatment, the water dispersion liquid of the prepared silver nanowires was applied using a spin coater so that the coated amount of the silver nanowires became 0.05 g/m², then it was dried. Then, after performing a calendar process to the coated layer of the silver nanowires, a stripe-like transparent pattern electrode TCF-1 with an electrode pattern width of 10 mm was produced with a well-known photolithography method.

Subsequently, to Baytron PH510 (made by H. C. Starck Co., Ltd., 1.3% of solid content) as a conductive polymer, which is a dispersion liquid of a mixture of PEDOT and PSS (polystyrene sulfonate) (mixing ratio of 1:2.5), was added hydroxypropyl methylcellulose (HPMC) 60SH (made by Shin-Etsu Chemical Co., Ltd.) as the 1^{st} water soluble binder resin so that the amount of HPMC became 30 weight % with respect to the solid content of the aforesaid conductive polymer. Further, a melamine resin BECKAMINE M-3 (made by DIC Corporation) as the 2^{nd} water soluble binder and a cross linkage accelerator CATALYST ACX (made by DIC Co., Ltd.) were added so that that the amount of each component became 10 weight % and 1 weight % with respect to the solid content of the conductive polymer, respectively. Transparent electrode TC-101 was produced by applying thus prepared coating solution with a spin coater on the transparent pattern electrode TCF-1, and dried at 120° C. for 30 minutes so that the dried coating thickness became 300 nm.

### (Preparation of Transparent Electrode TC-102: Present Invention)

Transparent electrode TC-102 was produced in the same manner as preparation of transparent electrode TC-101, except that hydroxypropyl methylcellulose (HPMC) 60SH (made by Shin-Etsu Chemical Co., Ltd.) used as the 1^{st} water soluble binder was replaced with a water soluble resin methylcellulose SM-100 (made by Shin-Etsu Chemical Co., Ltd.).

### (Preparation of Transparent Electrode TC-103: Present Invention)

Transparent electrode TC-103 was produced in the same manner as preparation of transparent electrode TC-101, except that hydroxypropyl methylcellulose (HPMC) 60SH (made by Shin-Etsu Chemical Co., Ltd.) used as the 1^{st} water soluble binder was replaced with a water soluble resin PVA 203 (made by Kuraray Co., Ltd.).

### (Preparation of Transparent Electrode TC-104: Present Invention)

Transparent electrode TC-104 was produced in the same manner as preparation of transparent electrode TC-101, except that hydroxypropyl methylcellulose (HPMC) 60SH (made by Shin-Etsu Chemical Co., Ltd.) used as the 1^{st} water soluble binder was replaced with a water soluble resin PHEA-1 (self-made compound).

In addition, PHEA-1 used above was prepared as follows.

### [Synthesis of PHEA-1]

To a 300 ml eggplant-shape flask were added 5.0 g (43.1 mmol, Fw 116.12) of 2-hydroxyethyl acrylate (made by Tokyo Chemicals Co., Ltd.), 0.7 g (4.3 mmol, Fw 164.21) of 2,2′-azobis(2-methylisopropionitrile) and 100 ml of tetrahydrofuran, then the mixture was heated to reflux for 8 hours. Then, the solution was cooled to room temperature and it was dropped into 2.0 L of methyl ethyl ketone agitated violently. After stirring the reaction solution for one hour, methyl ethyl ketone was eliminated by decantation, then, the polymer adhered to the wall of the flask was washed 3 times with 100 ml of methyl ethyl ketone. The polymer was dissolved in 100 ml of tetrahydrofuran and then it was moved to a 200 ml flask. Tetrahydrofuran was distilled away under a reduced pressure with a rotary evaporator. Then, by reducing the pressure at 80° C. for 3 hours to remove the remaining THF, 4.1 g (82% of yield) of PHEA-1 having the number average molecular weight 57,800 and molecular weight distribution 1.24 was obtained.

The structure and molecular weight of PHEA-1 were respectively measured with ¹H-NMR (400 MHz, made by JEOL Ltd.) and GPC (Waters 2695, made by Waters Co., Ltd.).

### <GPC Measurement Conditions>

### Apparatus: Wagers 2695 (Separations Module)

### Detector: Waters 2414 (Refractive Index Detector)

### Column: Shodex Asahipak GF-7M HQ

### Eluant: Dimethylformamide (20 mM LiBr)

Flow rate: 1.0 ml/min
Temperature: 40 degrees C.

### (Preparation of Transparent Electrode TC-105: Present Invention)

Transparent electrode TC-105 was produced in the same manner as preparation of transparent electrode TC-101, except the following changes were done to the coating solution: the amount of hydroxypropyl methylcellulose (HPMC) 60SH (made by Shin-Etsu Chemical Co., Ltd.) used as the 1^{st} water soluble binder was changed to 0.9 weight % with respect to the solid content of the conductive polymer; and further, the amount of a melamine resin BECKAMINE M-3 (made by DIC Co., Ltd.) as the 2^{nd} water soluble binder and a cross linkage accelerator CATALYST ACX (made by DIC Co., Ltd.) were changed respectively to 0.1 weight % and 0.01 weight % with respect to the solid content of the conductive polymer.

### (Preparation of Transparent Electrode TC-106: Present Invention)

Transparent electrode TC-106 was produced in the same manner as preparation of transparent electrode TC-101, except the following changes were done to the coating solution: the amount of hydroxypropyl methylcellulose (HPMC) 60SH (made by Shin-Etsu Chemical Co., Ltd.) used as the 1^{st} water soluble binder was changed to 4.5 weight % with respect to the solid content of the conductive polymer; and further, the amount of a melamine resin BECKAMINE M-3 (made by DIC Co., Ltd.) as the 2^{nd} water soluble binder and a cross linkage accelerator CATALYST ACX (made by DIC Co., Ltd.) were changed respectively to 0.5 weight % and 0.05 weight % with respect to the solid content of the conductive polymer.

### (Preparation of Transparent Electrode TC-107: Present Invention)

Transparent electrode TC-107 was produced in the same manner as preparation of transparent electrode TC-101, except the following changes were done to the coating solution: the amount of hydroxypropyl methylcellulose (HPMC) 60SH (made by Shin-Etsu Chemical Co., Ltd.) used as the 1^{st} water soluble binder was changed to 45 weight % with respect to the solid content of the conductive polymer; and further, the amount of a melamine resin BECKAMINE M-3 (made by DIC Co., Ltd.) as the 2^{nd} water soluble binder and a cross linkage accelerator CATALYST ACX (made by DIC Co., Ltd.) were changed respectively to 5 weight % and 0.5 weight % with respect to the solid content of the conductive polymer.

### (Preparation of Transparent Electrode TC-108: Present Invention)

Transparent electrode TC-108 was produced in the same manner as preparation of transparent electrode TC-101, except the following changes were done to the coating solution: the amount of hydroxypropyl methylcellulose (HPMC) 60SH (made by Shin-Etsu Chemical Co., Ltd.) used as the 1^{st} water soluble binder was changed to 180 weight % with respect to the solid content of the conductive polymer; and further, the amount of a melamine resin BECKAMINE M-3 (made by DIC Co., Ltd.) as the 2^{nd} water soluble binder and a cross linkage accelerator CATALYST ACX (made by DIC Co., Ltd.) were changed respectively to 20 weight % and 2 weight % with respect to the solid content of the conductive polymer.

### (Preparation of Transparent Electrode TC-109: Present Invention)

Transparent electrode TC-109 was produced in the same manner as preparation of transparent electrode TC-104, except that a cross linkage accelerator CATALYST ACX (made by DIC Co., Ltd.) was replaced with the same amount of glyoxal used as an aldehyde cross linking agent.

### (Preparation of Transparent Electrode TC-110: Present Invention)

Transparent electrode TC-110 was produced in the same manner as preparation of transparent electrode TC-101, except the following changes were done to the water dispersion of the silver nanowire: there was added carboxymethyl cellulose (made by Shin-Etsu Chemical Co., Ltd.) in an amount of 25 weight % with respect to the weight of silver, further there was added an aldehyde cross linking agent glyoxal in an amount of 10 weight % with respect to the weight of carboxymethylcellulose, and further there was added sulfuric acid and ammonia to adjust a pH value to be 7.3.

### (Preparation of Transparent Electrode TC-111: Present Invention)

Transparent electrode TC-111 was produced in the same manner as preparation of transparent electrode TC-101, except that the following changes were done to the water dispersion of the silver nanowire: there was added carboxymethyl cellulose (made by Shin-Etsu Chemical Co., Ltd.) in an amount of 5 weight % with respect to the weight of silver, further there was added PEDOT Denatron G-2001A (made by Nagase Chemtex Co., Ltd.) containing a heat curable resin, the amount of PEDOT Denatron G-2001A was 20 weight % as a solid content with respect to the weight of silver.

### (Preparation of Transparent Electrodes TC-112 to TC-118: The Present Invention)

Transparent electrodes TC-112 to TC-118 were produced in the same manner as preparation of transparent electrodes TC-101 to TC-104 and TC-109 to TC-111, except that Baytron PH510 (made by H. C. Starck Co., Ltd., 1.3% of solid content) used as a conductive polymer, which is a dispersion liquid of a mixture of PEDOT and PSS (polystyrene sulfonate) (mixing ratio of 1:2.5) was replaced with a dispersion of Polyaniline M (TA Chemical Co., Ltd., solid content of 6.0%) dispersed in pure water so as to be a concentration of 3 weight % as a conductive polymer.

### (Preparation of Transparent Electrodes TC-119 and TC-120: Comparative Samples)

Transparent electrodes TC-119 and TC-120 were produced in the same manner as preparation of transparent electrodes TC-101 and TC-112, except that hydroxypropyl methylcellulose (HPMC) 60SH (made by Shin-Etsu Chemical Co., Ltd.) as the 1^{st} water soluble binder resin, a melamine resin BECKAMINE M-3 (made by DIC Co., Ltd.) as the 2^{nd} water soluble binder and a cross linkage accelerator CATALYST ACX (made by DIC Co., Ltd.) were not added in the coating solution.

### (Preparation of Transparent Electrode TC-121: Comparative Sample)

Transparent electrode TC-121 was produced in the same manner as preparation of transparent electrode TC-101, except that the following changes were made to the coating solution: the amount of hydroxypropyl methylcellulose (HPMC) GOSH (made by Shin-Etsu Chemical Co., Ltd.) as the 1^{st} water soluble binder resin was changed to 0.45 weight % with respect to the solid content of the aforesaid conductive polymer; the amount of a melamine resin BECKAMINE M-3 (made by DIC Co., Ltd.) as the 2^{nd} water soluble binder and a cross linkage accelerator CATALYST ACX (made by DIC Co., Ltd.) were changed respectively to 0.05 weight % and 0.005 weight % with respect to the solid content of the aforesaid conductive polymer.

### (Preparation of Transparent Electrode TC-122: Comparative Sample)

Transparent electrode TC-122 was produced in the same manner as preparation of transparent electrode TC-101, except that the following changes were made to the coating solution: the amount of hydroxypropyl methylcellulose (HPMC) GOSH (made by Shin-Etsu Chemical Co., Ltd.) as the 1^{st} water soluble binder resin was changed to 225 weight % with respect to the solid content of the aforesaid conductive polymer; the amount of a melamine resin BECKAMINE M-3 (made by DIC Co., Ltd.) as the 2^{nd} water soluble binder and a cross linkage accelerator CATALYST ACX (made by DIC Co., Ltd.) were changed respectively to 25 weight % and 2.5 weight % with respect to the solid content of the aforesaid conductive polymer.

### (Preparation of Transparent Electrode TC-123: Comparative Sample)

Transparent electrode TC-123 was produced in the same manner as preparation of transparent electrode TC-101, except that the following changes were made to the coating solution: instead of adding hydroxypropyl methylcellulose (HPMC) 60SH (made by Shin-Etsu Chemical Co., Ltd.) as the 1^{st} water soluble binder resin, a melamine resin BECKAMINE M-3 (made by DIC Co., Ltd.) as the 2^{nd} water soluble binder and a cross linkage accelerator CATALYST ACX (made by DIC Co., Ltd.), VYLON UR-3220 (made by Toyobo Co., Ltd., 30% polyurethane resin MEK solution) was added in an amount of 30 weight % with respect to the solid content of the aforesaid conductive polymer.

### (Evaluation)

The total optical transmittance, surface resistivity, and surface smoothness (Ra, Ry) were measured using the following methods for transparent electrodes TC-101 to TC-123 produced as mentioned above. Moreover, in order to evaluate the stability of a transparent electrode, there were measured the total optical transmittance, surface resistivity, and surface smoothness (Ra, Ry) of the transparent electrode sample after subjected to the forced aging test accomplished by placing for three days under the ambient of 80° C. and 90% RH. The compositions of the prepared samples are shown in Table 1. The evaluation results are shown in Table 2.

### [Total Optical Transmittance]

Based on JIS K 7361-1:1997, it was measured using haze meter HGM-2B made by Suga Test Instruments Co., Ltd.

### [Surface Resistivity]

Based on JIS K 7194: 1994, it was measured using Mitsubishi Chemical Rolester GP (MCP-T610 type).

### [Surface Smoothness (Ra, Ry)]

An atomic force microscope (AFM) (SPI3800N probe station and SPA400 multifunctional-capability type module made by Seiko Instruments Co., Ltd.) was used. The sample cut off in a square having a side of about 1 cm was used and the measurement was carried out with the above-mentioned method based on the surface smoothness measurement specified by JIS B601 (1994).

TABLE 1

| | | Water soluble binder resin | | | | | Cross linking agent | |
|---|---|---|---|---|---|---|---|---|
| Transparent | Conductive | | Added | | Added | Total added | | Added |
| electrode No. | polymer | 1^{st} Kind | amount* | 2^{nd} Kind | amount* | amount | Kind | amount* |
| TC-101 | P-1 | HPMC60SH | 30 | BECKAMINE M-3 | 10 | 40 | CATALYST ACX | 1 |
| TC-102 | P-1 | HPMCSM-100 | 30 | BECKAMINE M-3 | 10 | 40 | CATALYST ACX | 1 |
| TC-103 | P-1 | PVA203 | 30 | BECKAMINE M-3 | 10 | 40 | CATALYST ACX | 1 |
| TC-104 | P-1 | PHEA-1 | 30 | BECKAMINE M-3 | 10 | 40 | CATALYST ACX | 1 |
| TC-105 | P-1 | HPMC60SH | 0.9 | BECKAMINE M-3 | 0.1 | 1 | CATALYST ACX | 0.01 |
| TC-106 | P-1 | HPMC60SH | 4.5 | BECKAMINE M-3 | 0.5 | 5 | CATALYST ACX | 0.05 |
| TC-107 | P-1 | HPMC60SH | 45 | BECKAMINE M-3 | 5 | 50 | CATALYST ACX | 0.5 |
| TC-108 | P-1 | HPMC60SH | 180 | BECKAMINE M-3 | 20 | 200 | CATALYST ACX | 2 |
| TC-109 | P-1 | PHEA-1 | 30 | BECKAMINE M-3 | 10 | 40 | GLYOXAL | 1 |
| TC-110 | P-1 | HPMC60SH | 30 | BECKAMINE M-3 | 10 | 40 | CATALYST ACX | 1 |
| TC-111 | P-1 | HPMC60SH | 30 | BECKAMINE M-3 | 10 | 40 | CATALYST ACX | 1 |
| TC-112 | P-2 | HPMC60SH | 30 | BECKAMINE M-3 | 10 | 40 | CATALYST ACX | 1 |
| TC-113 | P-2 | HPMCSM-100 | 30 | BECKAMINE M-3 | 10 | 40 | CATALYST ACX | 1 |
| TC-114 | P-2 | PVA203 | 30 | BECKAMINE M-3 | 10 | 40 | CATALYST ACX | 1 |
| TC-115 | P-2 | PHEA-1 | 30 | BECKAMINE M-3 | 10 | 40 | CATALYST ACX | 1 |
| TC-116 | P-2 | PHEA-1 | 30 | BECKAMINE M-3 | 10 | 40 | GLYOXAL | 1 |
| TC-117 | P-2 | HPMC60SH | 30 | BECKAMINE M-3 | 10 | 40 | CATALYST ACX | 1 |
| TC-118 | P-2 | HPMC60SH | 30 | BECKAMINE M-3 | 10 | 40 | CATALYST ACX | 1 |
| TC-119 | P-1 | — | — | — | — | — | — | — |
| TC-120 | P-2 | — | — | — | — | — | — | — |
| TC-121 | P-1 | HPMC60SH | 0.45 | BECKAMINE M-3 | 0.05 | 0.5 | CATALYST ACX | 0.015 |
| TC-122 | P-1 | HPMC60SH | 225 | BECKAMINE M-3 | 25 | 250 | CATALYST ACX | 2.5 |
| TC-123 | P-1 | POLYURETHANE | 30 | — | — | — | — | — |
| | | RESIN | | | | | | |

*Added amount: weight % of the water soluble binder resin with respect to the conductive polymer (solid content); (Weight of the water soluble binder resin/Weight of the conductive polymer) × 100,

### [Remarks on the Compounds Listed in Table 1]

### (Water Soluble Binder Resin):

HPMC60SH: Hydroxypropyl methylcellulose, (methoxy group; 27.5 to 31.5%, made by Shin-Etsu Chemical Co., Ltd.)
HPMC SM-100: Methyl cellulose (methoxy group; 28.0 to 30.01, hydroxypropoxy group; 7.0 to 12.01, made by Shin-Etsu Chemical Co., Ltd.)
PVA 203: Polyvinylalcohol (saponification degree; 87.0-89.0 mol %, made by Kuraray Co., Ltd.)
BECKAMINE M-3: Melamine resin (solid content; 851, made by DIC Co., Ltd.)
CATALYST ACX: Cross linkage accelerator (active ingredient; 35%, made by DIC Co., Ltd.)

### (Non-Water Solubility Binder Resin):

VYLON UR-3220: 30% polyurethane resin MEK solution, made by Toyobo Co., Ltd.)

### (Conductive Polymer):

P-1: Baytron PH510 which is a dispersion liquid of a mixture of PEDOT and PSS (Polystyrene Sulfonate) with a mixing ratio of 1:2.5 (made by C. H. Starck, solid content; 1.3%)
P-2: Poly aniline M (Poly Aniline, made by TA Chemical Co. Ltd., solid content; 6.0%)

TABLE 2

| | Stability | | | | | | | | |
|---|---|---|---|---|---|---|---|---|---|
| | Before subjected to forced | | | | After subjected to forced aging test | | | | |
| | aging test | | | | [80° C. 90% RH(3 day)] | | | | |
| | | Surface | | | | Surface | | | |
| Transparent | Total optical | resistivity | Ry | Ra | Total optical | resistivity | Ry | Ra | |
| electrode No. | transmittance | (Ω/□) | (nm) | (nm) | transmittance | (Ω/□) | (nm) | (nm) | Remarks |
| TC-101 | 84% | 10 | 27 | 5 | 84% | 15 | 31 | 7 | Invention |
| TC-102 | 83% | 10 | 29 | 4 | 83% | 13 | 34 | 7 | Invention |
| TC-103 | 84% | 10 | 23 | 2 | 83% | 11 | 29 | 5 | Invention |
| TC-104 | 83% | 10 | 25 | 3 | 82% | 12 | 32 | 14 | Invention |
| TC-105 | 80% | 10 | 28 | 3 | 80% | 11 | 47 | 13 | Invention |
| TC-106 | 81% | 13 | 24 | 4 | 80% | 15 | 41 | 11 | Invention |
| TC-107 | 85% | 18 | 26 | 5 | 84% | 18 | 37 | 15 | Invention |
| TC-108 | 87% | 20 | 27 | 3 | 85% | 24 | 48 | 14 | Invention |
| TC-109 | 83% | 10 | 19 | 3 | 84% | 11 | 26 | 6 | Invention |
| TC-110 | 82% | 10 | 22 | 4 | 81% | 16 | 27 | 6 | Invention |
| TC-111 | 82% | 10 | 26 | 3 | 82% | 14 | 30 | 5 | Invention |
| TC-112 | 82% | 10 | 36 | 5 | 80% | 17 | 42 | 7 | Invention |
| TC-113 | 82% | 10 | 32 | 5 | 82% | 19 | 44 | 9 | Invention |
| TC-114 | 81% | 10 | 31 | 4 | 82% | 16 | 40 | 10 | Invention |
| TC-115 | 82% | 10 | 31 | 5 | 82% | 14 | 37 | 8 | Invention |
| TC-116 | 82% | 10 | 34 | 5 | 82% | 16 | 36 | 9 | Invention |
| TC-117 | 81% | 10 | 33 | 3 | 80% | 15 | 45 | 8 | Invention |
| TC-118 | 81% | 10 | 31 | 4 | 81% | 13 | 41 | 8 | Invention |
| TC-119 | 78% | 10 | 35 | 7 | 73% | 37 | 157 | 20 | Comparison |
| TC-120 | 76% | 10 | 35 | 6 | 74% | 31 | 188 | 33 | Comparison |
| TC-121 | 79% | 12 | 33 | 9 | 78% | 29 | 84 | 19 | Comparison |
| TC-122 | 88% | 26 | 32 | 8 | 87% | 41 | 61 | 21 | Comparison |
| TC-123 | 87% | 30 | 37 | 8 | 86% | 48 | 389 | 72 | Comparison |

From the results shown in Table 2, it was revealed that transparent electrodes TC-119 to TC-123 exhibited inferior surface resistivity and surface smoothness after subjected to the forced aging test of placing for three days under the ambient of 80° C. and 90% RH compared with transparent electrode TC-101 to TC-118 of the present invention. Transparent electrodes TC-119 to TC-123 were prepared by any one of the following conditions: (i) incorporating only a conductive polymer on the silver nanowires, (ii) incorporating the water soluble binder in an amount of 0.5 weight % or 250 weight %, or (iii) incorporating only a polyurethane resin. On the other hand, it was shown that transparent electrodes TC-101 to TC-118 of the present invention exhibited more stable surface resistivity and surface smoothness.

### Example 2

### Preparation of Transparent Electrode TC-201

### Present Invention

A conductive polymer Baytron PH510 was condensed with a rotary evaporator to become the solid content of 13%. (Baytron PH510 is a dispersion liquid of a mixture of PEDOT and PSS (polystyrene sulfonate) (mixing ratio of 1:2.5), made by H. C. Starck Co., Ltd., 1.3% of solid content). Thus condensed Baytron PH510 was added to the silver nanowires in an amount of 3 times of the weight of the silver nanowires. Then, there was added hydroxypropyl methylcellulose (HPMC) 60SH (made by Shin-Etsu Chemical Co., Ltd.) as the 1^{st} water soluble binder resin so that the amount of it became 30 weight % with respect to the solid content of the aforesaid conductive polymer. Further there was added a melamine resin BECKAMINE M-3 (made by DIC Co., Ltd.) as the 2^{nd} water soluble binder and a cross linkage accelerator CATALYST ACX (made by DIC Co., Ltd.) so that that the amount of each component became 10 weight % and 1 weight %, respectively, with respect to the solid content of the 1^{st} water soluble binder resin (hydroxypropyl methylcellulose (HPMC)). Thus prepared coating solution was coated on a polyethylene terephthalate film support with a thickness of 100 μm which had been performed adhesion assisting treatment using a spin coater in an amount of the dried thickness to be 300 nm, and it was dried at 120° C. for 30 minutes.

### <Preparation of Metal Nanowire Removing Agent BF-1>

Composition of BF-1:

| | |
|---|---|
| Ethylenediaminetetraacetic acid Fe | 60 g |
| (III) ammonium salt | |
| Ethylenediaminetetraacetic acid | 2 g |
| Sodium metabisulfie | 15 g |
| Ammonium thiosulfate | 70 g |
| Maleic acid | 5 g |

Water was added to the above-described composition so that total volume became 1 L, then it was adjusted to pH 5.5 with an aqueous ammonia solution. Thus, metal nanowire removing agent BF-1 was prepared.

Subsequently, after performing a calender treatment to the coating layer of silver nanowires, gravure printing was applied to it with Gravure coating apparatus K Printing Proofer (made by MATSUO SANGYO Co., Ltd.) in the following way: a plate having a reverse pattern of a 10 mm stripe shaped pattern was set to K Printing Proofer; the viscosity of the prepared metal nanowire removing agent BF-1 was suitably adjusted with CMC; and gravure printing was performed so that the coating thickness on the silver nanowire coating layer became 30 μm by controlling the printing times. After printing, it was left still for 1 minute, subsequently rinsing treatment by running water was performed, and transparent electrode TC-201 was produced.

### (Preparation of Transparent Electrode TC-202: Present Invention)

Transparent electrode TC-202 was produced in the same manner as preparation of transparent electrode TC-201, except that hydroxypropyl methylcellulose (HPMC) 60SH (made by Shin-Etsu Chemical Co., Ltd.) used as the 1^{st} water soluble binder was replaced with a water soluble resin methylcellulose SM-100 (made by Shin-Etsu Chemical Co., Ltd.).

### (Preparation of Transparent Electrode TC-203: Present Invention)

Transparent electrode TC-203 was produced in the same manner as preparation of transparent electrode TC-201, except that hydroxypropyl methylcellulose (HPMC) 60SH (made by Shin-Etsu Chemical Co., Ltd.) used as the 1^{st} water soluble binder was replaced with a water soluble resin PVA 203 (made by Kuraray Co., Ltd.)

### (Preparation of Transparent Electrode TC-204: Present Invention)

Transparent electrode TC-204 was produced in the same manner as preparation of transparent electrode TC-201, except that hydroxypropyl methylcellulose (HPMC) 60SH (made by Shin-Etsu Chemical Co., Ltd.) used as the 1^{st} water soluble binder was replaced with a water soluble resin PHEA-1 (self-made compound).

### (Preparation of Transparent Electrode TC-205: Present Invention)

Transparent electrode TC-205 was produced in the same manner as preparation of transparent electrode TC-201, except the following changes were done to the coating solution: the amount of hydroxypropyl methylcellulose (HPMC) GOSH (made by Shin-Etsu Chemical Co., Ltd.) used as the 1^{st} water soluble binder was changed to 0.9 weight % with respect to the solid content of the conductive polymer; and further, the amount of a melamine resin BECKAMINE M-3 (made by DIC Co., Ltd.) as the 2^{nd} water soluble binder and a cross linkage accelerator CATALYST ACX (made by DIC Co., Ltd.) were changed respectively to 0.1 weight % and 0.01 weight % with respect to the solid content of the conductive polymer.

### (Preparation of Transparent Electrode TC-206: Present Invention)

Transparent electrode TC-206 was produced in the same manner as preparation of transparent electrode TC-201, except the following changes were done: the amount of hydroxypropyl methylcellulose (HPMC) GOSH (made by Shin-Etsu Chemical Co., Ltd.) used as the 1^{st} water soluble binder was changed to 4.5 weight % with respect to the solid content of the conductive polymer; and further, the amount of a melamine resin BECKAMINE M-3 (made by DIC Co., Ltd.) as the 2^{nd} water soluble binder and a cross linkage accelerator CATALYST ACX (made by DIC Co., Ltd.) were changed respectively to 0.5 weight and 0.05 weight % with respect to the solid content of the conductive polymer.

### (Preparation of Transparent Electrode TC-207: Present Invention)

Transparent electrode TC-207 was produced in the same manner as preparation of transparent electrode TC-201, except the following changes were done: the amount of hydroxypropyl methylcellulose (HPMC) 60SH (made by Shin-Etsu Chemical Co., Ltd.) used as the 1^{st} water soluble binder was changed to 45 weight with respect to the solid content of the conductive polymer; and further, the amount of a melamine resin BECKAMINE M-3 (made by DIC Co., Ltd.) as the 2^{nd} water soluble binder and a cross linkage accelerator CATALYST ACX (made by DIC Co., Ltd.) were changed respectively to 5 weight % and 0.5 weight % with respect to the solid content of the conductive polymer.

### (Preparation of Transparent Electrode TC-208: Present Invention)

Transparent electrode TC-208 was produced in the same manner as preparation of transparent electrode TC-201, except the following changes were done: the amount of hydroxypropyl methylcellulose (HPMC) 60SH (made by Shin-Etsu Chemical Co., Ltd.) used as the 1^{st} water soluble binder was changed to 180 weight with respect to the solid content of the conductive polymer; and further, the amount of a melamine resin BECKAMINE M-3 (made by DIC Co., Ltd.) as the 2^{nd} water soluble binder and a cross linkage accelerator CATALYST ACX (made by DIC Co., Ltd.) were changed respectively to 20 weight % and 2 weight % with respect to the solid content of the conductive polymer.

### (Preparation of Transparent Electrode TC-209: Present Invention)

Transparent electrode TC-209 was produced in the same manner as preparation of transparent electrode TC-204, except that a cross linkage accelerator CATALYST ACX (made by DIC Co., Ltd.) was replaced with the same amount of glyoxal used as an aldehyde cross linking agent.

### (Preparation of Transparent Electrode TC-210: Present Invention)

Transparent electrode TC-210 was produced in the same manner as preparation of transparent electrode TC-201, except the following changes were done to the water dispersion of the silver nanowire: there was added carboxymethyl cellulose (made by Shin-Etsu Chemical Co., Ltd.) in an amount of 25 weight % with respect to the weight of silver, further there was added an aldehyde cross linking agent glyoxal in an amount of 10 weight % with respect to the weight of carboxymethyl cellulose, and further there was added sulfuric acid and ammonia to adjust a pH value to be 7.3.

### (Preparation of Transparent Electrode TC-211: Present Invention)

Transparent electrode TC-211 was produced in the same manner as preparation of transparent electrode TC-201, except that the following changes were done to the water dispersion of the silver nanowire: there was added carboxymethyl cellulose (made by Shin-Etsu Chemical Co., Ltd.) in an amount of 5 weight % with respect to the weight of silver, further there was added PEDOT Denatron G-2001A (made by Nagase Chemtex Co., Ltd.) containing a heat curable resin, the amount of PEDOT Denatron G-2001A was 20 weight % as a solid content with respect to the weight of silver.

### (Preparation of Transparent Electrodes TC-212 to TC-218: The Present Invention)

Transparent electrodes TC-212 to TC-218 was produced in the same manner as preparation of transparent electrodes TC-201 to TC-204 and TC-209 to TC-211, except that Baytron PH510 (made by H. C. Starck Co., Ltd., 1.3% of solid content) used as a conductive polymer, which is a dispersion liquid of a mixture of PEDOT and PSS (polystyrene sulfonate) (mixing ratio of 1:2.5) was replaced with a dispersion of Polyaniline M (TA Chemical Co., Ltd., solid content of 6.0%) dispersed in pure water to be a concentration of 3 weight % as a conductive polymer.

### (Preparation of Transparent Electrodes TC-219 and TC-220: Comparative Samples)

Transparent electrodes TC-219 and TC-220 were produced in the same manner as preparation of transparent electrodes TC-201 and TC-212, except that hydroxypropyl methylcellulose (HPMC) 60SH (made by Shin-Etsu Chemical Co., Ltd.) as the 1^{st} water soluble binder resin, a melamine resin BECKAMINE M-3 (made by DIC Co., Ltd.) as the 2^{nd} water soluble binder and a cross linkage accelerator CATALYST ACX (made by DIC Co., Ltd.) were not added in the coating solution.

### (Preparation of Transparent Electrode TC-221: Comparative Sample)

Transparent electrode TC-221 was produced in the same manner as preparation of transparent electrode TC-201, except that the following changes were made to the coating solution: the amount of hydroxypropyl methylcellulose (HPMC) 60SH (made by Shin-Etsu Chemical Co., Ltd.) as the 1^{st} water soluble binder resin was changed to 0.45 weight % with respect to the solid content of the aforesaid conductive polymer; the amount of a melamine resin BECKAMINE M-3 (made by DIC Co., Ltd.) as the 2^{nd} water soluble binder and a cross linkage accelerator CATALYST ACX (made by DIC Co., Ltd.) were changed respectively to 0.05 weight % and 0.005 weight % with respect to the solid content of the aforesaid conductive polymer.

### (Preparation of Transparent Electrode TC-222: Comparative Sample)

Transparent electrode TC-222 was produced in the same manner as preparation of transparent electrode TC-201, except that the following changes were made to the coating solution: the amount of hydroxypropyl methylcellulose (HPMC) 60SH (made by Shin-Etsu Chemical Co., Ltd.) as the 1^{st} water soluble binder resin was changed to 225 weight % with respect to the solid content of the aforesaid conductive polymer; the amount of a melamine resin BECKAMINE M-3 (made by DIC Co., Ltd.) as the 2^{nd} water soluble binder and a cross linkage accelerator CATALYST ACX (made by DIC Co., Ltd.) were changed respectively to 25 weight % and 2.5 weight with respect to the solid content of the aforesaid conductive polymer.

### (Preparation of Transparent Electrode TC-223: Comparative Sample)

Transparent electrode TC-223 was produced in the same manner as preparation of transparent electrode TC-201, except that the following changes were made to the coating solution: instead of adding hydroxypropyl methylcellulose (HPMC) 60SH (made by Shin-Etsu Chemical Co., Ltd.) as the 1^{st} water soluble binder resin, a melamine resin BECKAMINE M-3 (made by DIC Co., Ltd.) as the 2^{nd} water soluble binder and a cross linkage accelerator CATALYST ACX (made by DIC Co., Ltd.), VYLON UR-3220 (made by Toyobo Co., Ltd., 30% polyurethane resin MEK solution) was added in an amount of 30 weight % with respect to the solid content of the aforesaid conductive polymer.

### (Evaluation)

The total optical transmittance, surface resistivity, and surface smoothness (Ra, Ry) were measured in the same manner as describe in Example 1 for transparent electrodes TC-201 to TC-223 produced as mentioned above. Moreover, in order to evaluate the stability of a transparent electrode, there were measured the total optical transmittance, surface resistivity, and surface smoothness (Ra, Ry) of the transparent electrode sample after subjected to the forced aging test accomplished by placing for three days under the ambient of 80° C. and 90% RH.

The compositions of the prepared samples are shown in Table 3. The evaluation results are shown in Table 4.

TABLE 3

| | | Water soluble binder resin | | | | | Cross linking agent | |
|---|---|---|---|---|---|---|---|---|
| Transparent | Conductive | | Added | | Added | Total added | | Added |
| electrode No. | polymer | 1^{st} Kind | amount* | 2^{nd} Kind | amount* | amount | Kind | amount* |
| TC-201 | P-1 | HPMC60SH | 30 | BECKAMINE M-3 | 10 | 40 | CATALYST ACX | 1 |
| TC-202 | P-1 | HPMCSM-100 | 30 | BECKAMINE M-3 | 10 | 40 | CATALYST ACX | 1 |
| TC-203 | P-1 | PVA203 | 30 | BECKAMINE M-3 | 10 | 40 | CATALYST ACX | 1 |
| TC-204 | P-1 | PHEA-1 | 30 | BECKAMINE M-3 | 10 | 40 | CATALYST ACX | 1 |
| TC-205 | P-1 | HPMC60SH | 0.9 | BECKAMINE M-3 | 0.1 | 1 | CATALYST ACX | 0.01 |
| TC-206 | P-1 | HPMC60SH | 4.5 | BECKAMINE M-3 | 0.5 | 5 | CATALYST ACX | 0.05 |
| TC-207 | P-1 | HPMC60SH | 45 | BECKAMINE M-3 | 5 | 50 | CATALYST ACX | 0.5 |
| TC-208 | P-1 | HPMC60SH | 180 | BECKAMINE M-3 | 20 | 200 | CATALYST ACX | 2 |
| TC-209 | P-1 | PHEA-1 | 30 | BECKAMINE M-3 | 10 | 40 | GLYOXAL | 1 |
| TC-210 | P-1 | HPMC60SH | 30 | BECKAMINE M-3 | 10 | 40 | CATALYST ACX | 1 |
| TC-211 | P-1 | HPMC60SH | 30 | BECKAMINE M-3 | 10 | 40 | CATALYST ACX | 1 |
| TC-212 | P-2 | HPMC60SH | 30 | BECKAMINE M-3 | 10 | 40 | CATALYST ACX | 1 |
| TC-213 | P-2 | HPMCSM-100 | 30 | BECKAMINE M-3 | 10 | 40 | CATALYST ACX | 1 |
| TC-214 | P-2 | PVA203 | 30 | BECKAMINE M-3 | 10 | 40 | CATALYST ACX | 1 |
| TC-215 | P-2 | PHEA-1 | 30 | BECKAMINE M-3 | 10 | 40 | CATALYST ACX | 1 |
| TC-216 | P-2 | PHEA-1 | 30 | BECKAMINE M-3 | 10 | 40 | GLYOXAL | 1 |
| TC-217 | P-2 | HPMC60SH | 30 | BECKAMINE M-3 | 10 | 40 | CATALYST ACX | 1 |
| TC-218 | P-2 | HPMC60SH | 30 | BECKAMINE M-3 | 10 | 40 | CATALYST ACX | 1 |
| TC-219 | P-1 | — | — | — | — | — | — | — |
| TC-220 | P-2 | — | — | — | — | — | — | — |
| TC-221 | P-1 | HPMC60SH | 0.45 | BECKAMINE M-3 | 0.05 | 0.5 | CATALYST ACX | 0.015 |
| TC-222 | P-1 | HPMC60SH | 225 | BECKAMINE M-3 | 25 | 250 | CATALYST ACX | 2.5 |
| TC-223 | P-1 | POLYURETHANE | 30 | — | — | — | — | — |
| | | RESIN | | | | | | |

*Added amount: weight % of the water soluble binder resin with respect to the conductive polymer (solid content); (Weight of the water soluble binder resin/Weight of the conductive polymer) × 100,

TABLE 4

| | Stability | | | | | | | | |
|---|---|---|---|---|---|---|---|---|---|
| | Before subjected to forced | | | | After subjected to forced aging test | | | | |
| | aging test | | | | [80° C. 90% RH(3 day)] | | | | |
| | | Surface | | | | Surface | | | |
| Transparent | Total optical | resistivity | Ry | Ra | Total optical | resistivity | Ry | Ra | |
| electrode No. | transmittance | (Ω/□) | (nm) | (nm) | transmittance | (Ω/□) | (nm) | (nm) | Remarks |
| TC-201 | 83% | 10 | 25 | 3 | 83% | 13 | 33 | 6 | Invention |
| TC-202 | 83% | 10 | 27 | 3 | 83% | 14 | 38 | 9 | Invention |
| TC-203 | 83% | 10 | 26 | 3 | 83% | 12 | 32 | 8 | Invention |
| TC-204 | 84% | 10 | 23 | 3 | 83% | 11 | 32 | 8 | Invention |
| TC-205 | 81% | 11 | 25 | 5 | 80% | 10 | 48 | 14 | Invention |
| TC-206 | 82% | 13 | 24 | 4 | 81% | 14 | 39 | 17 | Invention |
| TC-207 | 85% | 16 | 28 | 5 | 84% | 19 | 42 | 12 | Invention |
| TC-208 | 88% | 19 | 29 | 3 | 87% | 25 | 50 | 16 | Invention |
| TC-209 | 83% | 10 | 22 | 3 | 84% | 14 | 29 | 7 | Invention |
| TC-210 | 83% | 10 | 24 | 4 | 82% | 13 | 37 | 8 | Invention |
| TC-211 | 82% | 10 | 25 | 3 | 82% | 15 | 31 | 8 | Invention |
| TC-212 | 82% | 10 | 35 | 5 | 81% | 18 | 46 | 14 | Invention |
| TC-213 | 81% | 10 | 33 | 5 | 82% | 15 | 42 | 15 | Invention |
| TC-214 | 82% | 10 | 33 | 4 | 80% | 17 | 48 | 14 | Invention |
| TC-215 | 82% | 10 | 34 | 5 | 82% | 16 | 40 | 12 | Invention |
| TC-216 | 82% | 10 | 31 | 5 | 83% | 16 | 45 | 13 | Invention |
| TC-217 | 81% | 10 | 34 | 3 | 81% | 14 | 41 | 15 | Invention |
| TC-218 | 80% | 10 | 32 | 4 | 81% | 18 | 38 | 15 | Invention |
| TC-219 | 77% | 10 | 33 | 6 | 73% | 42 | 203 | 25 | Comparison |
| TC-220 | 75% | 10 | 37 | 6 | 71% | 39 | 167 | 37 | Comparison |
| TC-221 | 80% | 11 | 34 | 8 | 79% | 46 | 77 | 23 | Comparison |
| TC-222 | 87% | 28 | 33 | 7 | 85% | 52 | 82 | 27 | Comparison |
| TC-223 | 87% | 35 | 35 | 6 | 87% | 63 | 473 | 64 | Comparison |

From the results shown in Table 4, it was revealed that transparent electrodes TC-219 to TC-223 exhibited inferior surface resistivity and surface smoothness after subjected to the forced aging test of placing for three days under the ambient of 80° C. and 90% RH compared with transparent electrodes TC-201 to TC-218 of the present invention.

Transparent electrodes TC-219 and TC-220 were prepared by incorporating only a conductive polymer on the silver nanowires, transparent electrodes TC-221 and TC-222 were prepared respectively by incorporating the water soluble binder in an amount of 0.5 weight %, 250 weight %, and transparent electrodes TC-223 was prepared by incorporating only a polyurethane resin. On the other hand, it was shown that transparent electrodes TC-201 to 218 of the present invention exhibited more stable surface resistivity and surface smoothness.

### Example 3

### Preparation of Organic Electroluminescence Element

### Organic EL Element

Organic EL elements OEL-301 to OEL-323 were respectively produced in the following processes by using transparent electrodes TC-101 to TC-123 produced above for the 1^{st} electrode.

### <Formation of Positive Hole Transporting Layer>

The coating solution for a positive hole transporting layer was prepared by dissolving 4,4′-bis[(N-(1-naphthyl)-N-phenylamino)]biphenyl (NPD) in 1,2-dichloroethane so that the content of NPD became 1 weight %. This coating solution was coated on the 1^{st} electrode with a spin coating apparatus followed by drying at 80° C. for 60 minutes to form a positive hole transporting layer having a thickness of 40 nm.

### <Formation of Light Emission Layer>

The coating solution for forming light emission layer was prepared by dissolving polyvinyl carbazole (PVK) as a host material, 1 weight % of a red dopant material Btp₂Ir(acac), 2 weight of a green dopant material Ir(ppy)₃ and 3 weight % of a blue dopant material FIr(pic)₃ (the indicated weight % was based on the weight of PVK) in 1,2-dichloroethane so that the total solids content of PVK and the three dopants became 1 weight %. This coating solution was coated with a spin coating apparatus followed by drying at 100° C. for 10 minutes to form a light emission layer having a thickness of 60 nm.

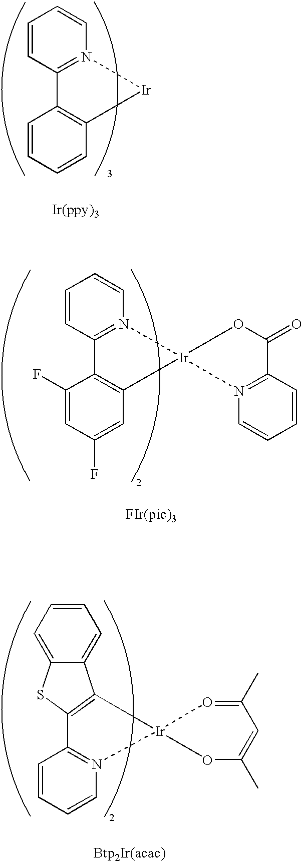

### <Formation of Electron Transporting Layer>

On the formed light emission layer, LiF was vapor-deposited as an electron transporting layer forming material under the vacuum of 5×10⁻⁴ Pa, and an electron transporting layer having a thickness of 0.5 nm was formed.

### <Formation of 2^{nd} Electrode>

On the formed electron transporting layer, aluminum was vapor-deposited as a 2^{nd} electrode forming material under the vacuum of 5×10⁻⁴ Pa, and a 2^{nd} electrode having a thickness of 100 nm was formed.

### <Formation of Sealing Film>

On the formed electron transporting layer, there was applied a flexible sealing member having a polyethylene terephthalate base on which was vapor-deposited Al₂O₃ with a thickness of 300 nm. In order to form external terminals for the 1^{st} electrode and the 2^{nd} electrode, the edge portion was eliminated and an adhesive agent was applied to the surrounding area of the 2^{nd} electrode. After sticking the flexible sealing member, the adhesive agent was cured with heating treatment.

### (Evaluation)

### [Uniformity of Luminescent Brightness]

Direct current voltage was impressed to the organic EL element to allow to emit light using Source Major Unit 2400 made by KEITHLEY Instrument Inc. For the organic EL elements OEL-301 to OEL-313 which were made to emit light with 200 cd/m², each luminescence uniformity was observed with a microscope at magnification of 50 times. Moreover, after the organic EL elements OEL-301 to OEL-323 were heated in an oven at 80° C. and 60% RH for 30 minutes, the aforesaid organic EL elements were left again at in an oven for 1 hour or more under the ambient of 23±3° C. and 55±3% RH. Then luminescence uniformity was observed similarly.

The evaluation criteria of luminescence homogeneity are as follows.

A: the whole EL element emits light uniformly.
B: the whole EL element is emits light almost uniformly.
C: slight ununiformity of luminescence is observed
D: markedly ununiformity of luminescence is observed

The above-mentioned evaluation results are shown in Table 5.

TABLE 5

| | | Uniformity of | | |
|---|---|---|---|---|
| | | luminescence | | |
| | | Before | After | |
| | 1^{st} electrode | subjected | subjected | |
| Organic EL | (Anode | to forced | to forced | |
| element | electrode) | aging | aging | Remarks |
| OEL-301 | TC-101 | A | A | Invention |
| OEL-302 | TC-102 | B | B | Invention |
| OEL-303 | TC-103 | A | A | Invention |
| OEL-304 | TC-104 | A | B | Invention |
| OEL-305 | TC-105 | B | B | Invention |
| OEL-306 | TC-106 | A | A | Invention |
| OEL-307 | TC-107 | A | B | Invention |
| OEL-308 | TC-108 | B | B | Invention |
| OEL-309 | TC-109 | A | A | Invention |
| OEL-310 | TC-110 | B | B | Invention |
| OEL-311 | TC-111 | A | A | Invention |
| OEL-312 | TC-112 | A | A | Invention |
| OEL-313 | TC-113 | B | B | Invention |
| OEL-314 | TC-114 | B | B | Invention |
| OEL-315 | TC-115 | A | A | Invention |
| OEL-316 | TC-116 | A | B | Invention |
| OEL-317 | TC-117 | B | B | Invention |
| OEL-318 | TC-118 | A | B | Invention |
| OEL-319 | TC-119 | B | C | Comparison |
| OEL-320 | TC-120 | B | C | Comparison |
| OEL-321 | TC-121 | B | D | Comparison |
| OEL-322 | TC-122 | B | C | Comparison |
| OEL-323 | TC-123 | C | D | Comparison |

It became clear from the evaluation results shown in Table 5 that the luminescence uniformity of organic EL elements OEL-319 to OEL-323 were remarkably deteriorated after subjected to heating at 80° C. and 60% RH for 30 minutes, while organic EL elements OEL-301 to OEL-318 of the present invention were stable even after subjected to heating.

### Example 4

### Preparation of Organic Electroluminescence Element

### Organic EL Element

Organic EL elements OEL-401 to OEL-423 were respectively prepared in the same manner as preparation process described in Example 3 by using transparent electrodes TC-201 to TC-223 produced above for the 1^{st} electrode.

Evaluation of organic EL elements were done in the same manner as evaluation described in Example 3.

The evaluation results are shown in Table 6.

TABLE 6

| | | Uniformity of | | |
|---|---|---|---|---|
| | | luminescence | | |
| | | Before | After | |
| | 1^{st} electrode | subjected | subjected | |
| Organic EL | (Anode | to forced | to forced | |
| element | electrode) | aging | aging | Remarks |
| OEL-401 | TC-201 | A | A | Invention |
| OEL-402 | TC-202 | A | B | Invention |
| OEL-403 | TC-203 | B | B | Invention |
| OEL-404 | TC-204 | A | A | Invention |
| OEL-405 | TC-205 | B | B | Invention |
| OEL-406 | TC-206 | A | B | Invention |
| OEL-407 | TC-207 | A | A | Invention |
| OEL-408 | TC-208 | B | B | Invention |
| OEL-409 | TC-209 | A | A | Invention |
| OEL-410 | TC-210 | A | B | Invention |
| OEL-411 | TC-211 | A | A | Invention |
| OEL-412 | TC-212 | B | A | Invention |
| OEL-413 | TC-213 | A | B | Invention |
| OEL-414 | TC-214 | B | B | Invention |
| OEL-415 | TC-215 | A | B | Invention |
| OEL-416 | TC-216 | A | A | Invention |
| OEL-417 | TC-217 | B | B | Invention |
| OEL-418 | TC-218 | A | A | Invention |
| OEL-419 | TC-219 | B | C | Comparison |
| OEL-420 | TC-220 | B | D | Comparison |
| OEL-421 | TC-221 | B | C | Comparison |
| OEL-422 | TC-222 | B | D | Comparison |
| OEL-423 | TC-223 | C | D | Comparison |

It became clear from the evaluation results shown in Table 6 that the luminescence uniformity of organic EL elements OEL-419 to OEL-423 were remarkably deteriorated after subjected to heating at 80° C. and 60% RH for 30 minutes, while organic EL elements OEL-401 to OEL-418 of the present invention were stable even after subjected to heating (forced aging).

### Example 5

### Preparation of Transparent Electrode TC-501

### Present Invention

Transparent electrode TC-501 was produced in the same manner as preparation of transparent electrode TC-101 in Example 1, except that the silver nanowires were replaced with SWCNT (HiPcoR monolayer carbon nanotubes, made by Unidym Co., Ltd.) and the amount of SWCNT was adjusted to be 50 Mg/m².

### (Preparation of Organic Electroluminescence Element (Organic EL Element))

Organic EL element OLE-501 was produced and evaluated like as in Example 3 by using the obtained transparent electrode as the 1^{st} electrode (anode electrode). It was confirmed that the produced organic EL element OLE-501 emitted light uniformly in the same manner as OLE-101. Moreover, uniform luminescence was observed in the whole of the organic EL element even after subjected to heating (forced aging) at 80° C. and 60% RH for 30 minutes.

### Example 6

### Preparation of Transparent Electrode TC-601

### Present Invention

Transparent electrode TC-601 was produced in the same manner as preparation of transparent electrode TC-201 described in Example 2, except that the silver nanowires were replaced with SWCNT (HiPcoR monolayer carbon nanotubes, made by Unidym Co.; Ltd.), without using the silver nanowire removing agent and the dispersion liquid was applied on the substrate by coating through the printing plate provided with a printing pattern having a stripe shape of 10 mm.

### (Preparation of Organic Electroluminescence Element (Organic EL Element))

Organic EL element OLE-601 was produced and evaluated like as in Example 3 by using the obtained transparent electrode as the 1^{st} electrode (anode electrode). It was confirmed that the produced organic EL element OLE-601 emitted light uniformly in the same manner as OLE-201. Moreover, uniform luminescence was observed in the whole of the organic EL element even after subjected to heating (forced aging) at 80° C. and 60% RH for 30 minutes.

### DESCRIPTION OF NUMBERS IN FIGS. 1A to 1C

11: Conductive fiber
21: Conductive material (conductive polymer)
31: Transparent conductive layer
41: Transparent resin (water soluble binder resin)
51: Transparent substrate

What is claimed is:

1. A transparent electrode comprising a transparent substrate having thereon a conductive fiber, a conductive polymer and a water soluble binder resin,
wherein a content of the water soluble binder resin is in the range of 1 to 200 weight % based on a weight of the conductive polymer.

2. The transparent electrode of claim 1,
wherein the transparent substrate is provided with a transparent conductive layer containing the conductive fiber, the conductive polymer and the water soluble binder resin, and a content of the water soluble binder resin is in the range of 1 to 200 weight % based on a weight of the conductive polymer.

3. The transparent electrode of claim 1,
wherein the transparent conductive layer comprises a first transparent conductive layer provided on the transparent substrate and a second transparent conductive layer provided on the first transparent conductive layer, the first transparent conductive layer containing the conductive fiber, and the second transparent conductive layer containing the conductive polymer and the water soluble binder resin, and a content of the water soluble binder resin is in the range of 1 to 200 weight % based on a weight of the conductive polymer.

4. The transparent electrode of claim 1,
wherein the content of the water soluble binder resin is in the range of 5 to 50 weight % based on the weight of the conductive polymer.

5. The transparent electrode of claim 1,
wherein the water soluble binder resin is a cross linking resin.

6. The transparent electrode of claim 1,
wherein the conductive fiber is a silver nanowire.

7. An electroluminescence element comprising the transparent electrode of claim 1.

8. A method for forming a transparent electrode comprising a step of:
applying a conductive fiber, a conductive polymer and a water soluble binder resin on a transparent substrate,
wherein a content of the water soluble binder resin is in the range of 1 to 200 weight % based on a weight of the conductive polymer.

9. The method for forming a transparent electrode of claim 8,
wherein the applying step is done by coating with an aqueous dispersion containing:
water;
the conductive fiber;
the conductive polymer; and
the water soluble binder resin.

10. The method for forming a transparent electrode of claim 8,
wherein the applying step comprises the flowing steps of:
coating a first solution containing the conductive fiber on the transparent substrate to form a first transparent conductive layer; and
coating a second solution containing the conductive polymer and the water soluble binder resin on the first transparent conductive layer to form a second transparent conductive layer.

11. The method for forming a transparent electrode claim 8,
wherein a content of the water soluble binder resin is in the range of 5 to 50 weight % based on a weight of the conductive polymer.

12. The method for forming a transparent electrode of claim 8,
wherein the water soluble binder resin is a cross linking resin.

13. The method for forming a transparent electrode of claim 8,
wherein the conductive fiber is a silver nanowire.
